(19) United States
(12) Patent Application Publication
(10) Pub. No.: US 2024/0061330 A1
(43) Pub. Date: Feb. 22, 2024

(54) MULTI-LAYERED MOLECULAR FILM PHOTORESIST HAVING MOLECULAR LINE STRUCTURE AND METHOD FOR MANUFACTURING SAME

(71) Applicant: IUCF-HYU (INDUSTRY-UNIVERSITY COOPERATION FOUNDATION HANYANG UNIVERSITY), Seoul (KR)

(72) Inventors: Myung Mo SUNG, Seoul (KR); Jinho AHN, Seoul (KR); Yeong Eun BAK, Seoul (KR); Hyeon Seok JI, Seoul (KR); Jae Hyuk LEE, Seoul (KR)

(73) Assignee: IUCF-HYU (INDUSTRY-UNIVERSITY COOPERATION FOUNDATION HANYANG UNIVERSITY), Seoul (KR)

(21) Appl. No.: 18/349,504

(22) Filed: Jul. 10, 2023

Related U.S. Application Data
(63) Continuation-in-part of application No. PCT/KR2022/012143, filed on Aug. 12, 2022.

(30) Foreign Application Priority Data
Aug. 12, 2021 (KR) 10-2021-0106631
Jan. 13, 2022 (KR) 10-2022-0005166
Aug. 12, 2022 (KR) 10-2022-0101505
Feb. 10, 2023 (KR) 10-2023-0017922

(51) Int. Cl. G03F 7/004; G03F 7/09

(52) U.S. Cl. CPC G03F 7/0042; G03F 7/094; G03F 7/0045

(57) ABSTRACT

A multilayer molecular film photoresist is provided. The multilayer molecular film photoresist comprises a plurality of molecular lines extending upwards above a substrate arranged in the horizontal direction. Each of the molecular lines includes a plurality of inorganic single molecules and an organic single molecule sandwiched between at least some of the inorganic single molecules, and these single molecules are connected by bonds.

### TECHNICAL FIELD

The present invention relates to a photoresist, and more particularly, to a photoresist for EUV.

### BACKGROUND ART

Research has been continuously conducted on photoresists, and in particular, the method of producing a liquid photoresist and then depositing it on a substrate by spin coating has been most actively studied. As such traditional photoresist, chemically amplified resist (CAR) containing polymer resin, PAG (Photo-Acid Generator), and base (quencher) is mainly used.

Recently, the semiconductor industry is introducing extreme ultraviolet (EUV) photolithography, which uses an EUV light source capable of forming ultra-fine patterns of 10 nm or less.

However, EUV has a low photon density of 1/14 compared to deep UV (DUV) of 193 nm, so it can cause stochastic failure, specifically photon shot noise. For example, in the case of the CAR, shot noise may occur due to low probability of PAG participating in the reaction due to low photon density. In addition, CAR is known to have the disadvantage of exhibiting relatively large line edge roughness because the size of the polymer resin particles is larger than 4 nm.

### DISCLOSURE

### Technical Problem

Therefore, the problem to be solved by the present invention is to provide a photoresist with excellent photon absorption and low line edge roughness and a method for manufacturing the same.

The technical problems of the present invention are not limited to the technical problems mentioned above, and other technical problems not mentioned will be clearly understood by those skilled in the art from the following description.

### Technical Solution

According to one embodiment of the present invention, a multilayer molecular film photoresist is provided. The multilayer molecular film photoresist has a plurality of molecular lines arranged in the horizontal direction. Each of the molecular lines extends upwards above a substrate. Each molecular line includes a plurality of inorganic single molecules and an organic single molecule sandwiched between at least some of the inorganic single molecules, and these single molecules are connected by bonds.

Van der Waals interaction may exist between the organic single molecules in horizontally adjacent molecular lines among the molecular lines. Each of the organic single molecules may have an aromatic ring or a linear or branched alkylene group, and the van der Waals interaction may be a π-π bond between the aromatic rings or a van der Waals interaction between the alkylene groups.

Within the each molecular line, the inorganic single molecules and the organic single molecules may be alternately stacked. The inorganic single molecule may be an organometallic single molecule containing Sn, Sb, Te, Bi, Zr, Al, Hf, Zn, In, Ti, Cu, W, or Si as a central metal.

Among the inorganic single molecules provided in the molecular lines, identical inorganic single molecules are located at the same level to form an inorganic monomolecular layer in the horizontal direction. Among the organic single molecules provided in the molecular lines, identical organic single molecules are located at the same level to form an organic monomolecular layer in the horizontal direction.

The multilayer molecular film photoresist may have at least one layer of a light-absorbing layer including a light-absorbing inorganic single molecule, a photoreactive layer including a photoreactive inorganic single molecule, and an etch-resistant layer including an etch-resistant inorganic single molecule. The light-absorbing inorganic single molecule may be an inorganic single molecule having a metal element having a d orbital. The metal element having the d orbital may be Sn, Sb, Te, or Bi. The photoreactive inorganic molecule may have a metal element such as Zr, Al, Hf, Zn, or In. The etch-resistant inorganic single molecule may have a metal element such as Al, Ti, W, Zn, Si, or Cu.

The multilayer molecular film photoresist may be a photoresist for EUV. According to one embodiment of the present invention, another example of a multilayer molecular film photoresist is provided. The multilayer molecular film photoresist has a plurality of molecular lines arranged in the horizontal direction. The molecular lines each extend upwards above a substrate. Each of the molecular lines has a portion represented by the following Formula 1.

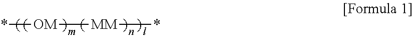

In Formula 1, one of the *s may be a bond with a functional group in a underlying portion, the other may be a bond with a functional group in an upper portion, MM may be an inorganic single molecule containing a metal element, OM may be an organic single molecule, and m may be 1 to 2, n may be 1 to 2, and 1 may be 1 to 1000.

Van der Waals interaction may exist between the organic single molecules in the horizontally adjacent molecular lines.

The organic single molecule may be represented by the following Formula 3.

*—X_{b}—Z₃—MR—Z₄—* [Formula 3]

In Formula 3, one of the *s may be a bond with a functional group in a underlying portion, the other may be a bond with a functional group in an upper portion. X_{b} may be O, S, Se, NR (R may be H or CH₃) or PR (R may be H or CH₃). MR may be a substituted or unsubstituted aromatic ring, a C1 to C18 substituted or unsubstituted linear alkylene group, or a C1 to C18 substituted or unsubstituted branched alkylene group. When MR is the aromatic ring, Z₃ and Z₄, regardless of each other, may be a bond, a substituted or unsubstituted linear alkylene group of C1 to C5, or a substituted or unsubstituted branched alkylene group of C1 to C5. When MR is the alkylene group, Z₃ and Z₄ may be bonds.

Van der Waals interaction may exist between the organic single molecules in the horizontally adjacent molecular lines. The van der Waals interaction may be a π-π bond between aromatic rings when the MR is an aromatic ring. When the MR is a linear or branched alkylene group, the van der Waals interaction may be a van der Waals interaction between alkylene groups.

The organic single molecule represented by Formula 3 may be an organic single molecule represented by Formula 3A below.

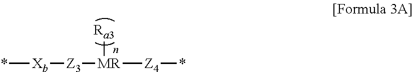

In Formula 3A, Rₐ₃ may be an alkyl group of C1 to C2, n may be 0 to 2, and *, X_{b}, MR, Z₃ and Z₄ are as defined in Formula 3 above. Specifically, the MR may be a C2 to C6 linear alkylene group.

The inorganic single molecule may be an organometallic single molecule represented by the following Formula 2.

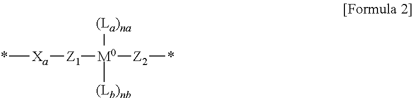

In Formula 2, one of the *s may be a bond with a functional group in a underlying portion, the other may be a bond with a functional group in an upper portion. Xₐ may be O, S, Se, NR (R may be H or CH₃) or PR (R may be H or CH₃). M⁰ may be a center metal and may be Sn, Sb, Te, Bi, Zr, Al, Hf, Zn, In, Al, Ti, Cu, W, or Si. Zi and Z₂, regardless of each other, may be a bond, C1 to C20 substituted or unsubstituted linear or branched alkylene group, C1 to C20 substituted or unsubstituted linear or branched alkylene oxide, C1 to C20 substituted or unsubstituted linear or branched alkyleneamino, C1 to C20 substituted or unsubstituted linear or branched alkylenesilylamino, C1 to C20 substituted or unsubstituted linear or branched alkylenethio, C1 to C20 substituted or unsubstituted linear or branched alkyleneseleno, or C1 to C20 substituted or unsubstituted linear or branched alkylenephosphino. Lₐ and L_{b} may be, regardless of each other, a halogen group, a C1 to C5 alkyl group, a C1 to C5 alkylsilylamino group, C1 to C5 alkoxy group, C1 to C5 alkylthio group, C1 to C5 alkylseleno group, C1 to C5 alkylamino group, C1 to C5 alkylphosphino group, acetate, or aryloxy. The sum of nₐ and n_{b}. may be an integer from 0 to 4.

In one example, nₐ and n_{b} may both be 0.

According to another embodiment of the present invention, multilayer molecular film photoresist deposition equipment may be provided. The multilayer molecular film photoresist deposition equipment may provide a multilayer molecular film photoresist including a plurality of molecular lines arranged in the horizontal direction. The molecular lines each extend upwards above a substrate. The multilayer molecular film photoresist is formed by performing multiple cycles including forming a metal monomolecular layer and forming an organic molecular layer on the substrate, thereby each of the molecular lines having a portion represented by the following Formula 1.

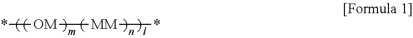

In Formula 1, one of the *s may be a bond with a functional group in a underlying portion, the other may be a bond with a functional group in an upper portion, MM may be an inorganic single molecule containing a metal element, OM may be an organic single molecule, and m may be 1 to 2, n may be 1 to 2, and 1 may be 1 to 1000.

The organic single molecule may be represented by the following Formula 3.

*—X_{b}—Z₃—MR—Z₄—* [Formula 3]

In Formula 3, one of the *s may be a bond with a functional group in a underlying portion, the other may be a bond with a functional group in an upper portion. X_{b} may be O, S, Se, NR (R may be H or CH₃) or PR (R may be H or CH₃). MR may be a substituted or unsubstituted aromatic ring, a C1 to C18 substituted or unsubstituted linear alkylene group, or a C1 to C18 substituted or unsubstituted branched alkylene group. When MR is the aromatic ring, Z₃ and Z₄, regardless of each other, may be a bond, a substituted or unsubstituted linear alkylene group of C1 to C5, or a substituted or unsubstituted branched alkylene group of C1 to C5. When MR is the alkylene group, Z₃ and Z₄ may be bonds.

In Formula 1, MM may be a light-absorbing inorganic single molecule containing a metal element having a d orbital, a photoreactive inorganic single molecule containing Zr, Al, Hf, Zn, or In, or an etch-resistant inorganic single molecule containing Al, Ti, Cu, W, or Zn.

### Advantageous Effect

In the multilayer molecular film photoresist according to an embodiment of the present invention, molecular lines, not particles, may be separated during exposure and development. Accordingly, Line Edge Roughness (LER), which refers to the lateral roughness of the pattern, can be very low at 1.2 nm or less, and resolution can also be greatly improved to 6 nm or less.

In addition, the multilayer molecular film photoresist can exhibit high photosensitivity (ex. 10 mJ/cm²) with low stochastic failure even for EUV, which has a low photon density.

### DESCRIPTION OF DRAWINGS

FIG. 1 is a schematic diagram showing a multilayer molecular film photoresist having a vertical molecular line structure according to an embodiment of the present invention.

FIG. 2 is a schematic diagram showing another example of a light-absorbing layer among the multilayer molecular film photoresist having a vertical molecular line structure according to an embodiment of the present invention.

FIG. 3 is a schematic diagram showing a multilayer molecular film photoresist having a vertical molecular line structure according to an embodiment of the present invention.

FIG. 4 is a schematic diagram showing an apparatus for manufacturing a multilayer molecular film photoresist having a vertical molecular line structure according to an embodiment of the present invention.

FIGS. 5 to 9 are schematic diagrams sequentially showing a photolithography method according to an embodiment of the present invention.

FIG. 10 is a schematic diagram showing a photolithography method according to another embodiment of the present invention, limited to the exposure step of FIG. 6.

FIG. 11 shows a unit cycle configuration for forming an inorganic molecular layer.

FIG. 12 is an SEM image taken after patterning the vertically designed inorganic multilayer molecular film photoresist formed with reference to FIG. 11.

FIG. 13 shows an example of a unit cycle configuration for forming a multilayer molecular film photoresist having a vertical molecular line structure.

FIG. 14 shows graphs showing the film thickness versus the number of unit cycle repetitions in manufacturing the Hf-based photoresist according to Preparation Example 1 and Comparative Example 1.

FIG. 15 is a schematic diagram showing expected unit product obtained through the reaction of the Hf precursor and organic precursor used in Preparation Example 1 and Comparative Example 1.

FIG. 16 shows graphs showing the film thickness versus the number of unit cycle repetitions in manufacturing the Zn-based photoresist according to Preparation Example 4 and Comparative Example 2.

FIGS. 17a, 17b, and 17c are SEM images taken after patterning the photoresist obtained in Preparation Examples 1 to 3, respectively.

FIG. 18 is a graph showing the sensitivity of the photoresist obtained in Preparation Examples 1 to 3 to electron beam.

FIG. 19 is a graph showing the sensitivity of the photoresist obtained in Preparation Example 4 to electron beam.

FIG. 20 is a graph showing the sensitivity of the photoresist obtained in Preparation Example 5 to electron beam.

FIG. 21 is a schematic diagram showing the form and dose conditions of EUV irradiation, and FIGS. 22, 23, and 24 show optical photos taken of photoresist patterns obtained after irradiating photoresists according to Preparation Example 1, Preparation Example 4, and Preparation Example 5 with EUV having the patterns shown in FIG. 21, respectively.

FIG. 25 is an AFM (Atomic force microscopy) image obtained after electron beam exposure and development of the photoresist using the Zn precursor according to Preparation Example 4, and FIG. 26 is an AFM (Atomic force microscopy) image obtained after electron beam exposure and development of a PMMA photoresist.

FIG. 27 shows graphs showing the film formation speed according to the supply time of each precursor in manufacturing the photoresist according to Preparation Example 6.

FIG. 28 is an SEM image taken after patterning the photoresist obtained in Preparation Example 6.

FIG. 29 is a graph showing the sensitivity of the photoresist obtained in Preparation Example 6 to electron beam.

FIG. 30 is an optical photograph of a photoresist pattern obtained by irradiating the photoresist according to Preparation Example 6 with EUV having the pattern shown in FIG. 21 and then developing it.

FIG. 31 is an SEM image of a photoresist pattern obtained by irradiating the photoresist according to Preparation Example 6 with EUV and then developing it.

FIGS. 32a and 32b show O1s XPS (X-ray Photoelectron spectroscopy) analysis data before and after EUV exposure to the photoresist according to Preparation Example 6, respectively.

### MODES OF THE INVENTION

In this specification, metal may include all metals, but as an example, it may be a transition metal, a post-transition metal, or a metalloid.

In this specification, the radiation may be EUV or E-beam, as an example. However, in some cases, it is not limited to this.

In this specification, a single molecule refers to a molecule that is not a polymer, and as an example, the single molecule refers to a small molecule, specifically, a molecule having 100 or less atoms, and specifically, 30 or less atoms.

In this specification, molecules or functional groups “connected by a bond” may mean that they are directly connected or indirectly connected by placing other molecule(s) or functional groups between them.

In this specification, when “CX to CY” is written in this specification, it should be interpreted as the numbers corresponding to all integers between carbon number X and carbon number Y are also written. For example, when C1 to C10 are described, it should be interpreted as C1, C2, C3, C4, C5, C6, C7, C8, C9, and C10 are all described.

In this specification, when “X to Y” is written in this specification, it should be interpreted as the numbers corresponding to all integers between X and Y are also written. For example, when 1 to 10 are written, it should be interpreted as 1, 2, 3, 4, 5, 6, 7, 8, 9, and 10 are all written.

In this specification, when referred to as an “aromatic ring”, it is an aromatic ring of 5 to 12 members, specifically 5 to 6 members, and has a homocyclic structure in which the constituent members are all carbon or heterocyclic structure in which some of the constituent members are substituted with heteroelements.

As used herein, the “alkylene group” or “alkyl group” may have all elements constituting the main chain of carbon, or some carbon may be substituted with O, S, N, C═O, or Si. The substituted element is not limited to this.

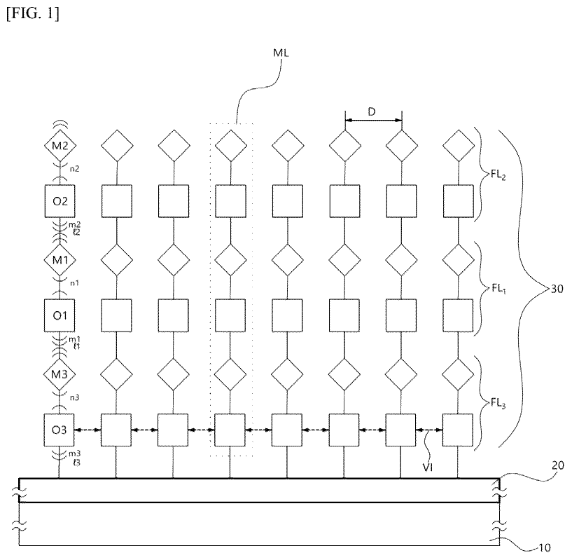

FIG. 1 is a schematic diagram showing a multilayer molecular film photoresist having a vertical molecular line structure according to an embodiment of the present invention. FIG. 3 is a schematic diagram showing a multilayer molecular film photoresist having a vertical molecular line structure according to an embodiment of the present invention.

Referring to FIGS. 1 and 3, a substrate 10 may be provided. The substrate may be a bare substrate such as a semiconductor substrate, a glass substrate, or a flexible substrate. For example, the flexible substrate may be a polymer substrate. On the substrate, at least one device (not shown) such as a transistor, memory, diode, solar cell, optical device, biosensor, nanoelectromechanical system (NEMS), microelectromechanical system (MEMS), nanodevice, or chemical sensor may have been formed. The device may be an organic electronic device such as an organic light-emitting diode or an organic solar cell. As such, in this embodiment, the substrate 10 may be the bare substrate, or a substrate including the device formed on the bare substrate.

An etch target layer 20 may be formed on the substrate 10. The etch target layer 20 is a layer that will be etched to form a pattern using a photoresist pattern as an etch mask after forming the photoresist pattern on the layer 20, and may be formed of various materials used in the semiconductor process. As an example, the etch target layer 20 may be a metal film, a semiconductor film, an insulating film, or a composite film containing any one of these. The metal film is used to form wiring, and may be aluminum, tungsten, titanium, or a composite film containing any one of these. The semiconductor film may be a silicon film, for example, a single crystal silicon film, a polysilicon film, an amorphous silicon film, or a composite film containing any one of these. The insulating film may include an inorganic insulating film such as a silicon oxide film or a silicon nitride film; an organic insulating film such as an amorphous carbon film; or a composite film containing any one of these. In one example, the etch target layer 20 may be the bare substrate.

The etch target layer 20 may have a hydroxyl group, a thiol group, an amine group, or a phosphine group as an example of a surface functional group, or may be surface-treated to have the same.

A multilayer molecular film photoresist 30 having a molecular line structure may be formed on the etch target layer 20.

The multilayer molecular film photoresist 30 may include a plurality of molecular lines ML adjacent to each other in the horizontal direction. Each molecular line ML includes inorganic single molecules (M1, M2, or M3) connected directly or indirectly by bonds. In this specification, the molecular line (ML) may be defined as a backbone, molecular chain, or main chain formed by single molecules connected by bonds. Additionally, the inorganic single molecules (M1, M2, or M3) may be organometallic single molecules. In this specification, the organometallic molecule may include a coordination compound. The indirect connection may mean that another single molecule, for example, an organic single molecule (O1, O2, or O3), which will be described later, or a functional group is bonded between the inorganic single molecules (M1, M2, or M3). The bond may be a covalent bond or a coordinate bond. In one example, the molecular lines ML may extend upward over the substrate 10, for example, may extend in a vertical direction with respect to the substrate 10. The horizontal direction may be a direction substantially parallel to the surface of the substrate 10.

In this embodiment, the multilayer molecular film photoresist 30 is formed using Atomic Layer Deposition or Molecular Layer Deposition, so that almost all molecular lines ML in the multilayer molecular film photoresist 30 may have substantially the same stacked structure. As a result, the molecular lines ML in the multilayer molecular film photoresist 30 may have substantially the same inorganic single molecules located at the same level and substantially the same organic single molecules located at the same level. Therefore, the inorganic single molecules located at the same level of the molecular lines ML may form an inorganic monomolecular layer in the horizontal direction; and the organic single molecules located at the same level of the molecular lines ML may form an organic monomolecular layer in the horizontal direction.

The multilayer molecular film photoresist 30 may be an organic/inorganic multilayer molecular film photoresist. Specifically, each molecular line ML in the multilayer molecular film photoresist 30 may have an organic single molecule O1, O2, O3 interposed and bonded between some of the inorganic single molecules M1, M2, M3. In this case, the multilayer molecular film photoresist 30 may include a plurality of molecular lines ML adjacent to each other in the horizontal direction, and each molecular line ML includes organic single molecules O1, O2, O3 and inorganic single molecules M1, M2, M3 connected by bonding. The multilayer molecular film photoresist 30 may have a van der Waals interaction VI between organic single molecules O1, O2, O3 in adjacent molecular lines ML among the molecular lines ML. The van der Waals interaction VI can play a role in stabilizing the horizontally adjacent molecular lines ML and preventing the pattern formed later from collapsing even when it has a high aspect ratio. In one example, the van der Waals interaction may be a van der Waals interaction between linear or branched alkylene groups, or a π-π bond between aromatic groups.

The multilayer molecular film photoresist 30 may have a structure represented by the following Formula 1.

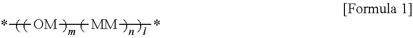

In Formula 1, one of the *s may be a bond to a functional group in an underlying layer or a functional group in an underlying single molecule, and the other one may be a bond to a functional group in an upper layer or a functional group in an upper single molecule. The bond may be, for example, a covalent bond. OM may be an organic single molecule. MM may be an inorganic single molecule containing a metal element, specifically an organometallic single molecule. In Formula 1, m may be 0 to 10, n may be 1 to 10, and 1 may be 1 to 10000, specifically 20 to 1000, and more specifically 25 to 100. Specifically, m may be 1 to 2, and as an example, m may be 1. n may also be 1 to 2, for example, n may be 1. Formula 1 may mean that the organic single molecule OM and the inorganic single molecules MM are sequentially stacked on the underlying layer, and also mean that inorganic single molecule MM and organic single molecule OM are sequentially stacked on the underlying layer.

In FIGS. 1, O1, O2, and O3 are all organic single molecules OM, which may refer to different organic single molecules, but are not limited to this, and all organic single molecules in each layer (FL₁, FL₂, and FL₃) may be the same. In addition, in FIG. 1, M1, M2, and M3 are all inorganic single molecules MM, which may mean that different inorganic single molecules are stacked, but are not limited to this, and all inorganic single molecules in each layer (FL₁, FL₂, and FL₃) may be the same. In addition, in FIG. 1, n1, n2, and n3 are the same as the values defined as n in Formula 1, regardless of each other, m1, m2, and m3 are the same as the values defined as m in Formula 1, regardless of each other, and 11, 12 and 13 are as defined as 1 in Formula 1 above, regardless of each other.

The organic single molecule OM may have an aromatic ring or a linear or branched alkylene group as a body and may be bonded to the underlying portion or underlying inorganic single molecule MM through O, S, Se, NR (R may be H or CH₃) or PR (R may be H or CH₃) directly or indirectly bonded to one end of the body. As an example, the OM may be an organic single molecule represented by Formula 3 below. In Formula 1, when m is 2 or more or 1 is 2 or more, the organic single molecules OM of each layer may be the same or different.

*—X_{b}—Z₃—MR—Z₄—* [Formula 3]

In Formula 3, one of the *s may be a bond with a functional group in a underlying layer or a functional group in a underlying organic or inorganic single molecule, and the other one may be a bond with a functional group in a upper layer or a functional group in a upper organic or inorganic single molecule. The bond may be, for example, a covalent bond. X_{b} may be O, S, Se, NR (R may be H or CH₃) or PR (R may be H or CH₃). In one example, X_{b} may be O.

In one example, MR of Formula 3 may be a substituted or unsubstituted aromatic ring. Substitution may be that any hydrogen of the aromatic ring is replaced with various functional groups. When MR is the aromatic ring, Z₃ and Z₄, regardless of each other, may be a bond, a substituted or unsubstituted C1 to C5 linear alkylene group, or a substituted or unsubstituted C1 to C5 branched alkylene group. The substitution may be performed by replacing any hydrogen of the alkylene group with any one of various functional groups, such as OH, SH, SeH, NR₂ (two Rs may be H or CH₃ regardless of each other), or PR₂ (two Rs may be H or CH₃ regardless of each other).

In another example, MR of Formula 3 may be a substituted or unsubstituted linear alkylene group of C1 to C18, specifically C2 to C6, or a substituted or unsubstituted branched alkylene group of C1 to C18, specifically C2 to C6. The substitution may be performed by replacing any hydrogen of alkylene group with a functional group that can crosslink by radiation, for example, a functional group containing a vinyl group, or by replacing any hydrogen of alkylene group with any one of various functional groups, such as OH, SH, SeH, NR₂ (two Rs may be H or CH₃ regardless of each other), PR₂ (two Rs may be H or CH₃ regardless of each other), or a C1 to C2 alkyl group (Rₐ₃ of Formula 3A). In addition, as previously defined, all of the elements constituting the main chain of the alkylene group may be carbons, or some of the carbons may be substituted with O, S, N, C═O, or Si, but the element replacing hydrogen is not limited to this. When MR is an alkylene group, Z₃ and Z₄ may be bonds.

The organic single molecule OM may further include C1 to C2 alkyl group(s) directly or indirectly bonded to the side of the body MR. Specifically, the organic single molecule OM represented by Formula 3 may be an organic single molecule represented by Formula 3A below.

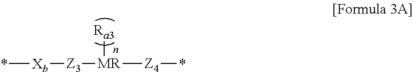

In Formula 3A, Rₐ₃ may be a C1 to C2 alkyl group. n may be 0 to 2. When n is 0, it may mean that the hydrogen of MR is not substituted with Rₐ₃, that is, the hydrogen remains as is or is substituted with another functional group as described above. When n is 2 or more, a plurality of Rₐ₃ may be bound to the same member within the MR or may be bound to different members. When bonded to the same member, their number may be limited to the number of possible covalent bonds of the member. —Rₐ₃ may be bonded to carbon or may be bonded to N or Si introduced by replacing carbon in MR. In Formula 3A, *, X_{b}, MR, Z₃ and Z₄ are as defined in Formula 3. In one example, MR may be a linear alkylene group of C1 to C18, specifically a linear alkylene group of C2 to C6.

MM may be an inorganic single molecule containing a metal element, specifically an organometallic single molecule. As an example, MM is a light-absorbing inorganic single molecule containing a metal element having a d orbital, a photoreactive inorganic single molecule containing Zr, Al, Hf, Zn, or In, or an etch-resistant inorganic single molecule containing Al, Ti, Cu, W, Si, or Zn. The metal element having the d orbital, specifically 4d or 5d orbital, may be Sn, Sb, Te, or Bi. Although inorganic single molecules have been classified by distinct functions, all of the described inorganic single molecules are capable of light-absorbing and photoreaction.

MM may be an organometallic single molecule having at least two organic functional groups or ligands, and it may be bonded to the underlying layer or the organic single molecule OM through O, S, Se, NR (R may be H or CH₃) or PR (R may be H or CH₃) which is directly or indirectly bonded to one end of the organic functional group or ligand. In other words, the central metal M⁰ of MM is directly or indirectly connected to the underlying layer or the underlying organic single molecule OM through O, S, Se, NR (R may be H or CH₃) or PR (R may be H or CH₃). The MM may be an organometallic single molecule represented by the following Formula 2, specifically the following Formulas 2A, 2B, or 2B.

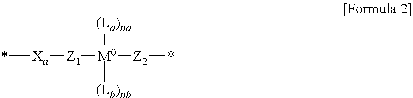

In Formula 2, one of the *s may be a bond with a functional group in the underlying layer or a underlying organic or inorganic single molecule (specifically its functional group), and the other one may be a bond with a functional group in the upper layer or an upper organic or inorganic single molecule (specifically its functional group). The bond may be, for example, a covalent bond. Z₁ and Z₂ may be, regardless of each other, a bond, a substituted or unsubstituted linear or branched alkylene group of C1 to C20, a substituted or unsubstituted linear or branched alkyleneoxide of C1 to C20, a substituted or unsubstituted linear or branched alkyleneamino of C1 to C20, a substituted or unsubstituted linear or branched alkylenesilylamino of C1 to C20, a substituted or unsubstituted linear or branched alkylenethio of C1 to C20, a substituted or unsubstituted linear or branched alkyleneseleno of C1 to C20, or a substituted or unsubstituted linear or branched alkylenephosphino of C1 to C20. M⁰ is the central metal and may be a light-absorbing metal atom having a d orbital, a photoreactive metal atom of Zr, Al, Hf, Zn, or In, or an etch-resistant metal atom of Al, Ti, Cu, W, or Zn. The metal element having the d orbital, specifically a 4d or 5d orbital, may be Sn, Sb, Te, or Bi. Xₐ may be O, S, Se, NR (R may be H or CH₃) or PR (R may be H or CH₃).

Lₐ and L_{b} are side ligands bound to M⁰ . The sum of na and nb, the number of Lₐ and L_{b}, may be determined by the maximum coordination number of M⁰ , and may be less than or equal to the number minus 2 (the number considering Z₁ and Z₂) from the maximum coordination number. For example, the sum of na and nb may be an integer from 0 to 4. Lₐ and L_{b}, regardless of each other, may be a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted, linear or branched alkyl groups. Additionally, in Formula 2, when na and/or nb are 2 or more, Lₐ and/or L_{b} may be selected, regardless of each other, among the above examples. In one example, when the sum of na and nb is 2 or more, two of Lₐ and L_{b} may be combined with M⁰ to which they are attached to form heterocyclyl or heteroaryl. Each bond between Z₁, Z₂, Lₐ, or L_{b} and M⁰ may be covalent or coordinate bond, regardless of the other.

In one example, the central metal M⁰ of the MM may connect to no side ligands Lₐ and L_{b}. In another example, if the central metal M⁰ of the MM connects to side ligand(s), the side ligand(s) may be air stable, that is, may be a ligand with high stability against moisture in the air. Stability against moisture may mean that no reaction occurs due to moisture. These side ligands may vary depending on the type of central metal M⁰. In this way, when the organometallic single molecule MM does not have a side ligand or has a side ligand(s) with air stability, it is possible to prevent crosslinking from forming due to reactions between the ligands caused by moisture in the air inside the photoresist during storage after forming the photoresist.

Specifically, when the sum of na and nb is 0, Lₐ and L_{b} (side ligand) are not bound to M⁰. Even when the sum of na and nb is 1 or more, which is the case Lₐ and L_{b} (side ligand) are bound to M⁰, and Lₐ and L_{b} may be air-stable, that is, may be ligands with high stability to moisture in the air. Stability against moisture may mean that no reaction occurs due to moisture. This may mean that these side ligands can be stably coordinated to the central metal M⁰, and may vary depending on the type of central metal M⁰.

As an example, Lₐ and L_{b} may be, regardless of each other, acetate, aryloxy (e.g., phenyloxy). When na is 2 or more, two of Lₐ s may be combined to form a β-diketonato ligand, e.g., acetylacetonato ligand. When nb is 2 or more, two of Lbs may be combined to become a β-diketonato ligand, for example, an acetylacetonato ligand.

Specifically, when M⁰ is Zn, the sum of na and nb may be 0. When M⁰ is Ti, na or nb may be 2 or more and the side ligand may be a β-diketonato produced by combining two Lₐs or two L_{b}s. When M⁰ is Hf, Lₐ and L_{b} may be, regardless of each other, acetate, aryloxy (for example, phenyloxy), or when na or nb may be 2 or more, side ligand may be a β-diketonato produced by combining two Lₐs or two L_{b}s. When M⁰ is Si, Lₐ and L_{b} may be, regardless of each other, a C1 to C5 alkyl group. In addition, when M⁰ is Al, Sb, or Sn, Lₐ and L_{b} may be, regardless of each other, a C1 to C5 alkylamino group, a C1 to C5 alkyl group, acetate, aryloxy (for example, phenyloxy), or when na or nb may be 2 or more, side ligand may be a β-diketonato produced by combining two Lₐs or two L_{b}s. Each bond between Z₁, Z₂, Lₐ, or L_{b} and M⁰ may be covalent or coordinate bond, regardless of the other.

In one example, the multilayer molecular film photoresist 30 may have at least one of a light-absorbing layer FL₁, a photoreactive layer FL₂, and an etch-resistant layer FL₃, which are classified according to the type of the inorganic single molecule, specifically the organometallic single molecule. As an example, the multilayer molecular film photoresist 30 may include one type of layer, two types of layers, or three types of layers. The classification of each layer may refer to a distinct main function, but all layers may generate secondary electrons due to light-absorbing and perform a photoreaction described later. As an example, the multilayer molecular film photoresist 30 may include at least a light-absorbing layer FL₁. The stacking order of the light-absorbing layer FL₁, the photoreactive layer FL₂, and the etch-resistant layer FL₃ may vary depending on the type of the etch target layer 20 and/or the type of pattern to be formed through photolithography.

The light-absorbing layer FL₁ may have excellent absorption of radiation, specifically EUV or E-beam, and may generate secondary electrons after absorbing the radiation. The light-absorbing layer FL₁ may have a structure represented by the following Formula 1A.

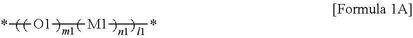

In Formula 1A, one of the *s may be a bond to a functional group in an underlying layer or a functional group in an underlying single molecule, and the other one may be a bond to a functional group in an upper layer or a functional group in an upper single molecule. The bond may be, for example, a covalent bond. M1 may be a light-absorbing inorganic single molecule, for example, an organometallic single molecule containing a metal element having a d orbital, specifically a 4d or 5d orbital. The metal element may be Sn, Sb, Te, or Bi. O1 may be an organic single molecule. m2 may be 0 to 10, n1 may be 1 to 10, and 11 may be 1 to 1000. Specifically, m2 may be 1 to 2, and as an example, m2 may be 1. n1 may also be 1 to 2, and as an example, n1 may be 1.

The light-absorbing inorganic single molecule M1 may be a light-absorbing organometallic single molecule represented by the following Formula 2A, and when n1 is 2 or more or 11 is 2 or more in the Formula 1A, the light-absorbing inorganic single molecule M1 of each layer may be the same or different from each other.

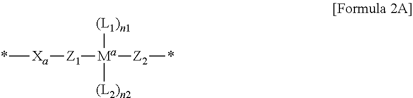

In Formula 2A, one of the *s may be a bond with a functional group in an underlying layer or a functional group in an underlying single molecule, and the other one may be a bond with a functional group in an upper layer or a functional group in an upper single molecule. The bond may be, for example, a covalent bond. Z₁ and Z₂ may be, regardless of each other, a bond, a substituted or unsubstituted linear or branched alkylene group of C1 to C20, a substituted or unsubstituted linear or branched alkyleneoxide of C1 to C20, a substituted or unsubstituted linear or branched alkyleneamino of C1 to C20, a substituted or unsubstituted linear or branched alkylenesilylamino of C1 to C20, a substituted or unsubstituted linear or branched alkylenethio of C1 to C20, a substituted or unsubstituted linear or branched alkyleneseleno of C1 to C20, or a substituted or unsubstituted linear or branched alkylenephosphino of C1 to C20. M^{a} may be an inorganic atom with excellent absorption of radiation, specifically EUV or E-beam. For example, M^{a} may be a metal atom having a d orbital, specifically, a 4d or 5d orbital. The metal atom may be Sn, Sb, Te, or Bi. Xₐ may be O, S, Se, NR (R may be H or CH₃) or PR (R may be H or CH₃).

In Formula 2A, L₁ and L₂ are side ligands bound to M^{a}. The sum of n1 and n2, the number of L₁ and L₂, may be determined by the maximum coordination number of M^{a}, and may be less than or equal to the number that the maximum coordination number minus 2 (the number considering Z₁ and Z₂). For example, the sum of n1 and n2 may be an integer from 0 to 4. L₁ and L₂, regardless of each other, may be a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted, linear or branched alkyl groups. Additionally, in Formula 2A, when n1 and/or n2 are 2 or more, L₁ and/or L₂ may be selected, regardless of each other, among the above examples. In one example, when the sum of n1 and n2 is 2 or more, two of L₁ and L₂ may be combined with M^{a} to which they are attached to form heterocyclyl or heteroaryl. Each bond between Z₁, Z₂, Li, or L₂ and M^{a} may be covalent or coordinate bond, regardless of the other.

The organic single molecule O1 may be represented by Formula 3, and when ml is 2 or more or 11 is 2 or more in Formula 1A, the organic single molecule O1 in each layer may be the same or different from each other.

The multilayer molecular film photoresist 30 may include a photoreactive layer FL₂, for example, in addition to the light-absorbing layer FL₁. The photoreactive layer FL₂ may have a layer structure represented by the following Formula 1B.

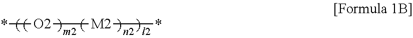

In Formula 1B, one of the *s may be a bond to a functional group in an underlying layer or a functional group in an underlying single molecule, and the other one may be a bond to a functional group in an upper layer or a functional group in an upper single molecule. The bond may be, for example, a covalent bond. M2 may be a photoreactive inorganic single molecule, specifically an organometallic single molecule containing Zr, Al, Hf, Zn, or In. O2 may be an organic single molecule. m2 may be 0 to 10, n2 may be 1 to 10, and 12 may be 1 to 1000. Specifically, m2 may be 1 to 2, and as an example, m2 may be 1. n2 may also be 1 to 2, for example, n2 may be 1.

The photoreactive inorganic single molecule M2 may be a photoreactive organometallic single molecule represented by the following Formula 2B, and when n2 is 2 or more or 12 is 2 or more in the Formula 1B, the photoreactive inorganic single molecule M2 of each layer may be the same or different from each other.

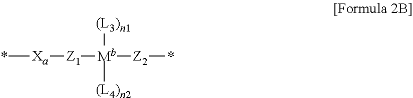

In Formula 2B, one of the *s may be a bond with a functional group in a underlying layer or a functional group in a underlying single molecule, and the other one may be a bond with a functional group in a upper layer or a functional group in a upper single molecule. The bond may be, for example, a covalent bond. Z₁ and Z₂ may be, regardless of each other, a bond, a substituted or unsubstituted linear or branched alkylene group of C1 to C20, a substituted or unsubstituted linear or branched alkyleneoxide of C1 to C20, a substituted or unsubstituted linear or branched alkyleneamino of C1 to C20, a substituted or unsubstituted linear or branched alkylenesilylamino of C1 to C20, a substituted or unsubstituted linear or branched alkylenethio of C1 to C20, a substituted or unsubstituted linear or branched alkyleneseleno of C1 to C20, or a substituted or unsubstituted linear or branched alkylenephosphino of C1 to C20. M^{b} may be a metal atom, specifically, Zr, Al, Hf, Zn, or In. Xₐ may be O, S, Se, NR (R may be H or CH₃) or PR (R may be H or CH₃).

L₃ and L₄ are side ligands bound to M^{b}. The sum of n1 and n2, the number of L₃ and L₄, may be determined by the maximum coordination number of M^{b}, and may be less than or equal to the number that the maximum coordination number minus 2 (the number considering Z₁ and Z2). For example, the sum of n1 and n2 may be an integer from 0 to 4. L₃ and L₄, regardless of each other, may be a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted, linear or branched alkyl groups. Additionally, in Formula 2B, when n1 and/or n2 are 2 or more, L₃ and/or L₄ may be selected, regardless of each other, among the above examples. In one example, when the sum of n1 and n2 is 2 or more, two of L₃ and L₄ may be combined with M^{b} to which they are attached to form heterocyclyl or heteroaryl. Each bond between Z₁, Z₂, L₃, or L₄ and M^{b} may be covalent or coordinate bond, regardless of the other.

The organic single molecule O2 may be represented by Formula 3. However, it may be the same as or different from the organic single molecule O1 in the light-absorbing layer FL₁. When m2 is 2 or more or 12 is 2 or more in Formula 1B, the organic single molecule O2 in each layer may be the same or different from each other.

Crosslinks may be formed between the photoreactive inorganic single molecules M2 in adjacent molecular lines ML by secondary electrons generated in the light-absorbing layer FL₁ upon radiation exposure or generated from the metal included in the photoreactive inorganic single molecule M₂ and/or in the etch-resistant inorganic single molecule M₃ described below upon radiation exposure. Specifically, M^{b}-L₄ and L₃-M^{b} bonds between adjacent photoreactive inorganic single molecules M₂ may react by the secondary electrons to form M^{b}-Y₂-M^{b} bond. In another example, when the sum of n1 and n2 is 0, M^{b} in the photoreactive inorganic single molecule M₂ may form a bond, for example, a coordination bond with Xₐ and/or X_{b} of another adjacent molecular line. In another example, when the sum of n1 and n2 is 1, M^{b} in the photoreactive metal single molecule M₂ may be bonded to, as an example, coordinate with Xₐ and/or X_{b} of another adjacent molecular line, or M^{b}-L₃ and L₃-Mb bonds may react by the secondary electrons to form M^{b}-Y₂-M b bond. This M^{b}-Y₂-M b bond and the bond between M^{b} and Xₐ and/or X_{b} may not be etched by a developer, for example a developing gas or developing plasma, that develops a multilayer molecular film photoresist pattern formed by exposure. For this purpose, the type of M^{b} can be selected as above. Y₂ may be O, S, Se, N, or P.

However, it is not limited to this, and crosslinks may also be formed between the light-absorbing inorganic single molecules M1 in the adjacent molecular lines ML by secondary electrons generated during radiation exposure in the light-absorbing layer FL₁. Specifically, M^{a}-L₂ and L₁-M^{a} bonds between the adjacent light-absorbing inorganic single molecules M1 may react by the secondary electrons to form M^{a}-Y₁-M^{a} bonds. In another example, when the sum of n1 and n2 is 0, M^{a} in the light-absorbing metal single molecule M1 may form a bond, for example a coordination bond, with Xₐ and/or X_{b} of another adjacent molecular line. In another example, when the sum of n1 and n2 is 1, M^{a} in the light-absorbing metal single molecule M1 may be bonded to, as an example, coordinate with Xₐ and/or X_{b} of another adjacent molecular line, or M^{a}-L₁ and L₁-M^{a} bonds may react by the secondary electrons to form M^{a}-Y₁-M^{a} bond. This M^{a}-Y₁-M^{a} bond and the bond between M^{a} and Xₐ and/or X_{b} may also not be etched by the developer. Yi may be O, S, Se, N, or P.

The multilayer molecular film photoresist 30 may include an etch-resistant layer FL₃, for example, in addition to the light-absorbing layer FL₁. The etch-resistant layer FL₃ may have a layer structure represented by the following Formula 1C.

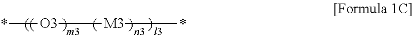

In Formula 1C, one of the *s may be a bond to a functional group in an underlying layer or a functional group in an underlying single molecule, and the other one may be a bond to a functional group in an upper layer or a functional group in an upper single molecule. The bond may be, for example, a covalent bond. M₃ may be a etch-resistant inorganic single molecule, specifically an organometallic single molecule containing Al, Ti, Cu, W, or Zn. O3 may be an organic single molecule. m3 may be 0 to 10, n3 may be 1 to 10, and 13 may be 1 to 1000. Specifically, m3 may be 1 to 2, and as an example, m3 may be 1. n3 may also be 1 to 2, for example, n3 may be 1.

The etch-resistant inorganic single molecule M₃ may be a etch-resistant organometallic single molecule represented by the following Formula 2C, and when n3 is 2 or more or 13 is 2 or more in the Formula 1C, the etch-resistant inorganic single molecule M₃ of each layer may be the same or different from each other.

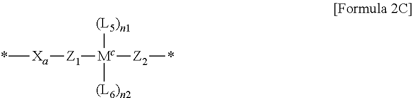

In Formula 2C, one of the *s may be a bond with a functional group in an underlying layer or a functional group in an underlying single molecule, and the other one may be a bond with a functional group in an upper layer or a functional group in an upper single molecule. The bond may be, for example, a covalent bond. Z₁ and Z₂ may be, regardless of each other, a bond, a substituted or unsubstituted linear or branched alkylene group of C1 to C20, a substituted or unsubstituted linear or branched alkyleneoxide of C1 to C20, a substituted or unsubstituted linear or branched alkyleneamino of C1 to C20, a substituted or unsubstituted linear or branched alkylenesilylamino of C1 to C20, a substituted or unsubstituted linear or branched alkylenethio of C1 to C20, a substituted or unsubstituted linear or branched alkyleneseleno of C1 to C20, or a substituted or unsubstituted linear or branched alkylenephosphino of C1 to C20. MC may be a metal atom, specifically, Al, Ti, W, Zn, or Cu. Xₐ may be O, S, Se, NR (R may be H or CH₃) or PR (R may be H or CH₃).

L₅ and L₆ are ligands bound to M^{c}. The sum of n1 and n2, the number of L₅ and L₆, may be determined by the maximum coordination number of M^{c}, and may be less than or equal to the number that the maximum coordination number minus 2 (the number considering Z₁ and Z₂). For example, the sum of n1 and n2 may be an integer from 0 to 4. Ls and L₆, regardless of each other, may be a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted, linear or branched alkyl groups. Additionally, in Formula 2C, when n1 and/or n2 are 2 or more, L₅ and/or L₆ may be selected, regardless of each other, among the above examples. In one example, when the sum of n1 and n2 is 2 or more, two of L₅ and L₆ may be combined with M^{c} to which they are attached to form heterocyclyl or heteroaryl. Each bond between Z₁, Z₂, L₅, or L₆ and M^{c} may be covalent or coordinate bond, regardless of the other.

The organic single molecule O3 may be represented by Formula 3. However, it may be the same as or different from the organic single molecule O1 in the light-absorbing layer FL₁ or the organic single molecule O2 in the photoreactive layer FL₂. When m3 is 2 or more or 13 is 2 or more in Formula 1C, the organic single molecule O3 in each layer may be the same or different from each other.

Crosslinks may be formed between the etch-resistant inorganic single molecules M₃ in adjacent molecular lines ML by secondary electrons generated in the light-absorbing layer FL₁ upon radiation exposure or generated from the metal included in the photoreactive inorganic single molecule M₂ and/or in the etch-resistant inorganic single molecule M₃ upon radiation exposure. Specifically, M^{c}-L₅ and L₆-M^{c} bonds between the adjacent etch-resistant inorganic single molecules M₃ may react by the secondary electrons to form M^{c}-Y₃-M^{c} bond. In another example, when the sum of n1 and n2 is 0, M^{c} in the etch-resistant inorganic single molecule M₃ may form a bond, for example, a coordination bond with Xₐ and/or X_{b} of another adjacent molecular line. In another example, when the sum of n1 and n2 is 1, M^{c} in the etch-resistant metal single molecule M₃ may be bonded to, as an example, coordinate with Xₐ and/or X_{b} of another adjacent molecular line, or M^{c}-L₅ and L₅-M^{c} bonds may react by the secondary electrons to form M^{c}-Y₃-M^{c} bond. This M^{c}-Y₃-M^{c} bond and the bond between M^{c} and Xₐ and/or X_{b} may not be etched by a developer, and may further not be etched by an etchant, for example plasma, for etching the etch target layer 20. For this purpose, the type of M^{c} can be selected as above. Y₃ may be O, S, Se, N, or P.

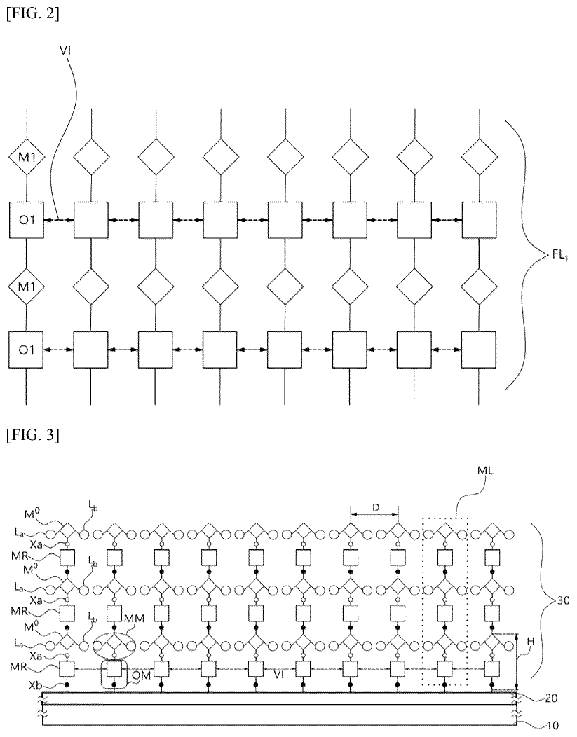

FIG. 2 is a schematic diagram showing another example of a light-absorbing layer in the multilayer molecular film photoresist having a vertical molecular line structure according to an embodiment of the present invention.

The light-absorbing layer FL₁ shown in FIG. 2 is a case in which m1 in FIG. 1 is 1, n1 in FIG. 1 is 1, and 11 in FIG. 1 is 2. Although the light-absorbing layer FL₁ is shown as an example in FIG. 2, the photoreactive layer FL₂ and/or the etch-resistant layer FL₃ of FIG. 1 may also have one of these exemplary structures.

As such, when m, m1, m2, m3 and n, n1, n2, and n3 in the Formulas 1, 1A, 1B, or 1C are all 1, the multilayer molecular film photoresist 30 may have a structure in which an inorganic single molecule (MM, M1, M2, or M3) and organic single molecules (OM, O1, O2, or O3) are alternately stacked. In this case, organic single molecule (OM, O1, O2, or O3) is placed between inorganic single molecules (MM, M1, M2, or M3), and both the inorganic single molecule (MM, M1, M2, or M3) and the organic single molecule (OM, O1, O2, or O3) can be self-assembled on the underlying layer or underlying single molecule. As a result, the molecular lines ML may extend upward, for example, vertically, with respect to the substrate 10 and may be spaced apart from each other.

The van der Waals interaction VI between organic single molecules (OM, O1, O2, or O3) in adjacent molecular lines ML among the plurality of molecular lines ML may stabilize molecular lines ML adjacent to each other in the horizontal direction, thereby preventing the pattern from collapsing even when it has a high aspect ratio. In one example, the van der Waals interaction may be a van der Waals interaction between linear or branched alkylene groups, or a π-π bond between aromatic groups.

As described above, when the organic single molecule OM further has a C1 to C2 alkyl group(s) (Rₐ₃ in Formula 3A) bonded directly or indirectly to the side of the body (MR in Formula 3 and Formula 3A), Van der Waals interactions between organic single molecules OM can become greater.

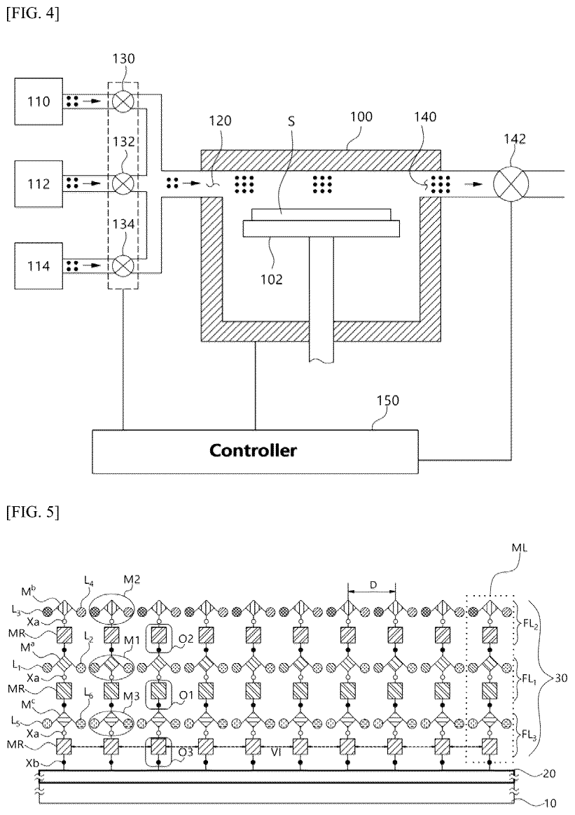

FIG. 4 is a schematic diagram showing an apparatus for manufacturing a multilayer molecular film photoresist having a vertical molecular line structure according to an embodiment of the present invention.

Referring to FIGS. 3 and 4 simultaneously, a substrate S may be loaded on a stage 102 in a chamber 100 having a gas inlet 120 and a gas outlet 140. The substrate S may be the substrate 10 on which an etch target layer 20 described with reference to FIG. 1 is formed.

Before loading the substrate S, the chamber 100 may be heated and maintained at a deposition temperature by the controller 150. The deposition temperature may be 20 to 250° C., 50 to 200° C., 70 to 150° C., 90 to 140° C., or 100 to 130° C. The gas outlet 140 may be connected to a vacuum pump.

First, a vacuum inside the chamber 100 may be created by closing all the gas inlet valves 130, 132, and 134 connected to the gas inlet 120 and opening the gas outlet valve 142 connected to the gas outlet 140.

Thereafter, the multilayer molecular film photoresist 30 can be formed by performing a cycle including forming a metal molecular layer (MM) and forming an organic molecular layer (OM). In this specification, a unit cycle including forming an organic molecular layer (OM) and then forming a metal molecular layer (MM) is described, but it is not limited to this, and the unit cycle may include forming the organic molecular layer (OM) after forming the metal molecular layer (MM).

In forming the organic molecular layer (OM), an organic molecule layer unit cycle may be performed. The organic molecule layer unit cycle may include an organic precursor dosing step of dosing an organic precursor and chemically bonding the organic precursor to the underlying layer through self-assembly; and a purge step of supplying a purge gas to purge unreacted organic precursors and reaction by-products.

The organic precursor has a body which is an aromatic ring or a linear or branched alkylene group, ORₐ₁, SRₐ₁, SeRₐ₁, NRRₐ₁ (R may be H or CH₃) or PRRₐ₁ (R may be H or CH₃) directly or indirectly bonded to one end of the body, and ORₐ₂ , SRₐ₂, SeRₐ₂, NRRₐ₂ (R may be H or CH₃) or PRRₐ₂ (R may be H or CH₃) directly or indirectly bonded to the other end of the body. Rₐ₁ and Rₐ₂ may be hydrogen or a C1 to C2 alkyl group regardless of each other.

In one example, the organic precursor may be represented by Formula 4 below.

Rₐ₁X_{b}—Z₃—MR—Z₄—XₐRₐ₂ [Formula 4]

In Formula 4, Rₐ₁ and Rₐ₂ may be hydrogen or a C1 to C2 alkyl group regardless of each other, and X_{b} and Xₐ may be O, S, Se, NR (R may be H or CH₃) or PR (R may be H or CH₃) regardless of each other. As an example, X_{b} may be 0 and Xₐ may be S. Meanwhile, Z₃, Z₄, and MR are as defined in Formula 3 above.

Specific examples of the organic precursor may be as follows.

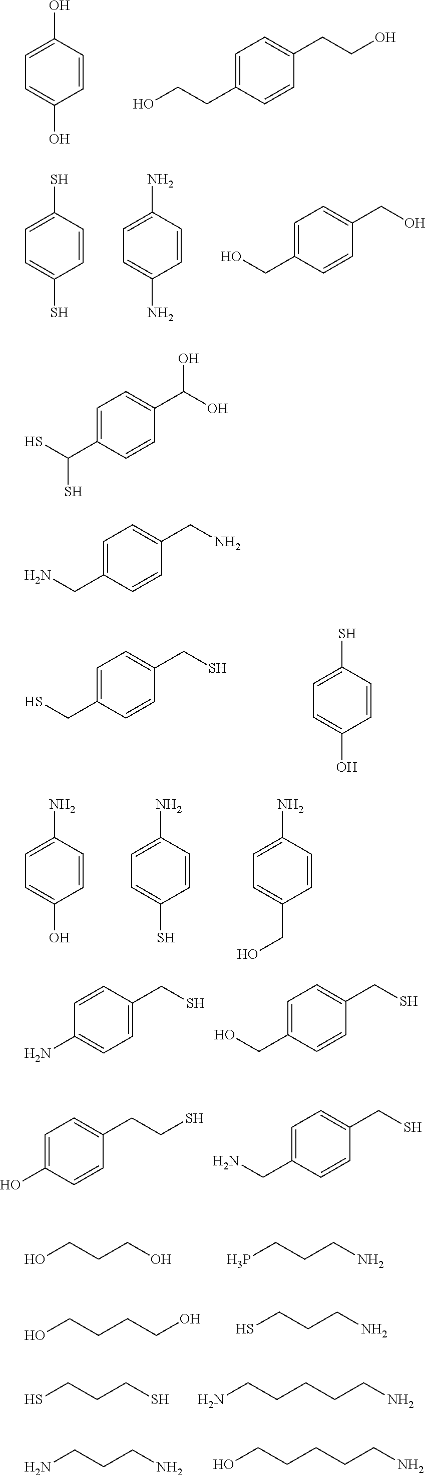

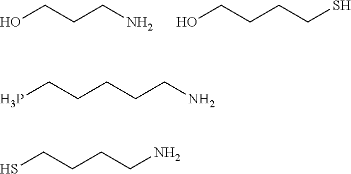

In the organic precursor dosing step, a reaction according to Scheme 1 below may occur.

—R₀+Rₐ₁X_{b}—Z₃—MR—Z₄—XₐRₐ₂→*—X_{b}—Z₃—MR—Z₄—XₐRₐ₂+R₀Rₐ₁ [Scheme 1]

In Scheme 1, R₀ is a functional group on the surface of the underlying layer, and R₀ may be hydrogen, a hydroxy group, a thiol group, an amine group, a phosphine group, a C1 to C5 alkyl group, a C1 to C5 alkoxy, a C1 to C5 alkylthio group, a C1 to C5 alkylseleno group, a C1 to C5 alkylamine group, or a C1 to C5 alkylphosphino group. Rₐ₁X_{b}—Z₃—MR—Z₄—XₐRₐ₂ is an organic precursor, and each functional group is as defined in Formula 4 above. When X_{b} and Xₐ are different from each other, the more reactive functional group may combine with the surface functional group of the underlying layer. As an example, when X_{b} and Xₐ are O and S, respectively, O may combine with the surface functional group of the underlying layer.

In one embodiment, the organic precursor may further include C1 to C2 alkyl group(s) directly or indirectly bonded to the side of the body MR. This organic precursor may be represented by the following Formula 4A, which is an example of Formula 4.

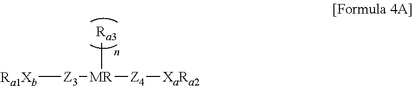

In the above formula 4A, Rₐ₁ and Rₐ₂ may be hydrogen or a C1 to C2 alkyl group regardless of each other, and X_{b} and Xₐ may be O, S, Se, NR (R may be H or CH₃) or PR (R may be H or CH₃) regardless of each other. As an example, X_{b} may be O and Xₐ may be S. Meanwhile, Z₃, Z₄, Rₐ₃, n, and MR are as defined in Formula 3A above.

Specific examples of the organic precursor represented by Formula 4A may be as follows.

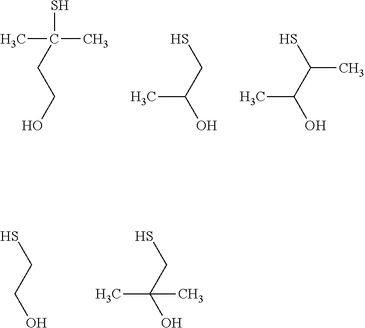

In the organic precursor dosing step, the organic precursor represented by Formula 4A may undergo a reaction according to Scheme 1A below. Scheme 1A below corresponds to a specific example of Scheme 1 above.

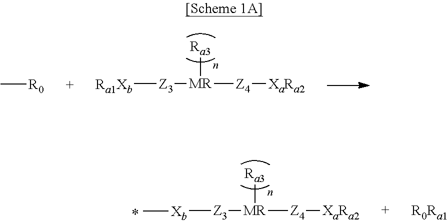

In Scheme 1A, R₀ is as defined in Scheme 1, Rₐ₁X_{b}—Z₃—MR(—Z₄—XₐRₐ₂)(—Rₐ₃)ₙ is an organic precursor, and each functional group is as defined in Formula 4A. When X_{b} and Xₐ are different from each other, the more reactive functional group may combine with a surface functional group of an underlying layer. As an example, when X_{b} and Xₐ are O and S, respectively, O may combine with the surface functional group of an underlying layer.

Referring to Scheme 1 and Scheme 1A, the organic precursor may self-assemble on an underlying layer by reacting with the functional group on the surface of the underlying layer. During this process, R₀Rₐ₁ may be generated as a reaction by-product. After this, remaining excess organic precursor and reaction by-products can be purged in the purge step.

In the organic precursor dosing step, the organic precursor may be supplied from the organic precursor storage unit 114 into the chamber 100 with the organic precursor control valve 134 opened and the gas outlet valve 142 closed (organic precursor supply step). The organic precursor within the organic precursor storage unit 114 may be stored in a solid, liquid, or gaseous state. The organic precursor storage unit 114 may be heated and the organic precursor may be supplied into the chamber 100 at a predetermined vapor pressure. In one embodiment, the organic precursor may be supplied without a carrier gas. In other words, the organic precursor alone may be supplied into the chamber 100.

Since the organic precursor is supplied with the gas outlet valve 142 closed, it may accumulate in the chamber 100 and increase the pressure within the chamber 100. The organic precursor may be supplied until the pressure of the chamber 100 reaches the reaction pressure (organic precursor supply step). The reaction pressure may be the pressure of the organic precursor alone in the chamber 100, and may be in the range of 10 mTorr to 10 Torr, specifically 50 mTorr to 10 Torr, 100 mTorr to 6 Torr, 130 mTorr to 3 Torr, and 150 mTorr to 1 Torr, 500 mTorr to 2.7 Torr, or 1.5 Torr to 2.5 Torr. Typically, the precursor is dosed into the chamber along with a carrier gas, and considering that the partial pressure of the precursor in this case is about 1 to 10 mTorr, a pressure greater than 50 mTorr of the pressure of the organic precursor alone in chamber 100 may mean that the organic precursor may be in a pressurized state.

When the reaction pressure is reached, the organic precursor control valve 134 may be closed, and the chamber may be sealed for a predetermined period of time while the gas outlet valve 142 is closed (organic precursor exposure step). The organic precursor supply step and the organic precursor exposure step may be referred to as an organic precursor dosing step. However, the organic precursor exposure step may be omitted in some cases. In the organic precursor dosing step, the reaction according to Scheme 1 may occur.

After this, the chamber 100 can be purged (organic precursor purge step). Specifically, the purge gas control valve 132 and the gas outlet valve 142 are opened to flow the purge gas in the purge gas storage unit 112 onto the surface of the substrate to remove unreacted excess organic precursor and the reaction by-products. The purge gas is an inert gas, and the inert gas may include, for example, argon (Ar), nitrogen (N₂), or a combination thereof.

In the step of forming the metal monomolecular layer (MM), a unit cycle including a metal precursor dosing step of dosing a metal precursor and chemically bonding the metal precursor to the underlying layer by self-assembly; and a purge step of purging unreacted metal precursors and reaction by-products by supplying a purge gas may be performed.

The metal precursor may be an organometallic single molecule having at least two organic functional groups or ligands. The metal precursor may be represented by the following Formula 5.

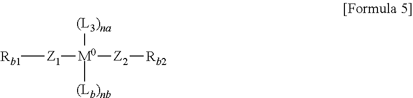

In Formula 5, R_{b1} and R_{b2} are, regardless of each other, a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted linear or branched alkyl groups. Z₁, Z₂, Lₐ, L_{b}, na, nb, and M⁰ are as defined in Formula 2. In addition, in some cases, two of R_{b1}, R_{b2}, Lₐ, and L_{b} may be combined with M⁰ to which they are directly or indirectly bonded to form heterocyclyl or heteroaryl. Alternatively, at least one of R_{b1} and R_{b2} may be coordinated to M⁰.

As an example, Z₁ and Z₂ may be bonds, and Lₐ, L_{b}, Rbl, and R_{b2} may be the same functional groups. As another example, Z₁ and Z₂ may be bonds, Lₐ and L_{b} may be the same functional groups, and R_{b1} and R_{b2} may be the same functional groups, but Lₐ and R_{b1} may be different functional groups.

The metal precursor may be a metal precursor represented by the following Formulas 5A, 5B, and 5C and specific examples thereof, or may be a metal precursor shown below.

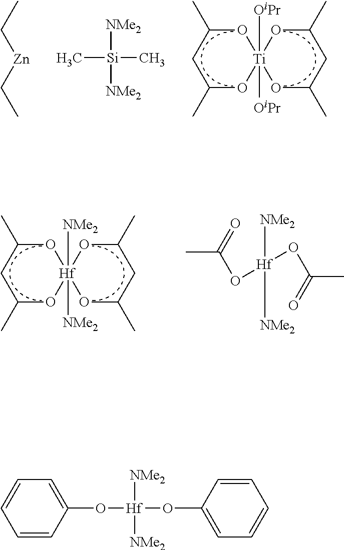

In the metal precursor dosing step, a reaction according to Scheme 2 below may occur.

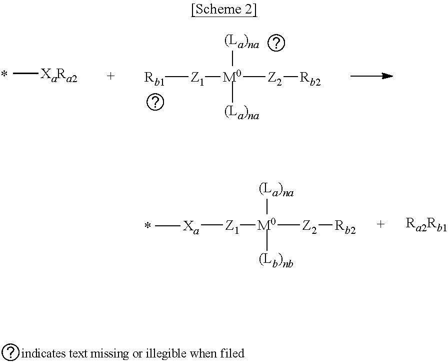

In Scheme 2, *—XₐRₐ₂ may be a surface functional group of the underlying layer, specifically, the surface functional group of the organic molecular layer O formed previously. The metal precursor of Formula 5 may self-assemble on the surface of the organic molecular layer O by reacting with the surface functional group of the previously formed organic molecular layer O. Thus, it can be self-assembled on the surface of the organic molecular layer O. During this process, Rₐ₂R_{b1} may be produced as a reaction by-product. After this, the remaining metal precursor and the reaction by-products may be purged in the purge step. In Scheme 2, each functional group may be the same as defined in Formula 4 and Formula 5.

Specifically, the metal precursor may be represented by the following formula 5A, 5B, or 5C. Additionally, specifically, in the metal precursor dosing step, the reaction according to Scheme 2 may be embodied as a reaction according to Schemes 2A, 2B, or 2C below.

In the metal precursor dosing step, the metal precursor gas may be supplied from the metal precursor storage unit 110 into the chamber 100 with the metal precursor gas control valve 130 opened and the gas outlet valve 142 closed (metal precursor supply step). The metal precursor within the metal precursor storage unit 110 may be stored in a solid, liquid, or gaseous state. The metal precursor storage unit 110 may be heated below the thermal decomposition temperature of the metal precursor, and thus the metal precursor can be supplied into the chamber 100 at a predetermined vapor pressure. The metal precursor may be supplied without a carrier gas. In other words, the metal precursor alone may be supplied into the chamber 100.

Since the metal precursor is supplied with the gas outlet valve 142 closed, the metal precursor may accumulate in the chamber 100 and increase the pressure within the chamber 100. The metal precursor may be supplied until the pressure of the chamber 100 reaches the reaction pressure (metal precursor supply step). The reaction pressure may be the pressure of the metal precursor alone in the chamber 100 in the range of 10 mTorr to 10 Torr, specifically 50 mTorr to 10 Torr, 100 mTorr to 6 Torr, 600 mTorr to 5 Torr, or 700 mTorr to 2 Torr. Typically, the precursor is dosed into the chamber along with a carrier gas, and considering that the partial pressure of the precursor in this case is about 1 mTorr, a pressure of 50 mTorr or more of the metal precursor alone in the chamber 100 indicates that the metal precursor may be in a pressurized state.

When the reaction pressure is reached, the metal precursor gas control valve 130 may be closed and the chamber may be sealed for a predetermined period of time (metal precursor exposure step). The metal precursor supply step and the metal precursor exposure step may be referred to as a metal precursor dosing step. However, the metal precursor exposure step may be omitted in some cases. In the metal precursor dosing step, a reaction according to Scheme 2 may occur.

After this, the chamber 100 may be purged (metal precursor purge step). Specifically, the purge gas control valve 132 and the gas outlet valve 142 are opened to allow the purge gas in the purge gas storage unit 112 to flow onto the surface of the substrate in the chamber to remove excess metal precursor gas that is not adsorbed on the surface of the substrate and the reaction by-products. The purge gas is an inert gas, and the inert gas may include, for example, argon (Ar), nitrogen (N₂), or a combination thereof.

Unlike shown, when the metal monomolecular layer (MM) is formed in multiple layers (when n in Formula 1 is 2 or more), after performing the metal precursor dosing step and purge step according to Scheme 4 described above, a unit cycle comprising a reaction gas dosing step of dosing a reaction gas to react with the metal precursor chemically bonded to the underlying layer, a purge step of supplying a purge gas to purge unreacted reaction gas and reaction by-products, the metal precursor dosing step, and the purge step may be repeated n-1 times. The reaction gas may be hydrogen, a gas containing oxygen (ex. O₂, O₃, H₂O), or a gas containing nitrogen (ex. NH₃).

The controller 150 may control the opening and closing of the valves and the temperature of the chamber.

In this way, the reaction shown in Scheme 1 may proceed in a pressurized environment where the pressure of the organic precursor alone is 50 mTorr or more, specifically 100 mTorr or more. In this case, the organic precursor may react densely on the substrate, so that the main chain of the organic precursor may be disposed upward, for example, vertically, with respect to the substrate 10. Furthermore, the reaction shown in Scheme 1 may be carried out with the gas outlet valve 142 closed, that is, specifically, in a pressurized stagnant environment rather than a lamina flow environment. In this case, the reaction of the organic precursor at a higher density on the substrate can proceed more efficiently. However, it is not limited to this, and even if the organic precursor reacts in a state in which a lamina flow is formed in the chamber with the gas outlet valve 142 open, it can react densely on the substrate because it is supplied alone without a carrier gas. In this way, when the organic precursor reacts densely on the substrate, the gap between the organic single molecules formed by the organic precursor becomes narrow enough to allow van der Waals interaction between them, and the molecular line (ML in FIGS. 1 and 3) can be formed effectively. However, it appears that the reaction in a pressurized stagnant environment can further narrow the gap between organic single molecules.

The molecular layer deposition equipment according to an embodiment of the present invention performs a plurality of cycles including forming a metal monomolecular layer (MM in Formula 1) and forming an organic molecular layer (OM in Formula 1). Specifically, it can perform the number of times indicated by 1 of Formula 1.

FIGS. 5 to 9 are schematic diagrams sequentially showing a photolithography method according to an embodiment of the present invention. For convenience of explanation, FIGS. 5 to 9 illustrate the case where n1, n2, n3, m1, m2, m3, 11, 12, and 13 of FIG. 1 are all 1 in the multilayer molecular film photoresist 30 and the case where both Z₃ and Z₄ are bonds in Formula 3, which represents an organic single molecule, both Z₁ and Z₂ are bonds in Formulas 2A, 2B, and 2C, which represent inorganic single molecules M1, M2, M3, and all of n1 and n2 are 1.

Referring to FIG. 5, a substrate 10 on which a etch target layer 20 is formed may be provided. The substrate 10 and the etch target layer 20 may be the same as those described with reference to FIG. 1.

A multilayer molecular film photoresist 30 may be formed on the etch target layer 20. The multilayer molecular film photoresist 30 may be the same as the embodiment described with reference to FIG. 1 except as described later. In one embodiment, the multilayer molecular film photoresist 30 is described as an example in which an etch-resistant layer FL₃, a light-absorbing layer FL₁, and a photoreactive layer FL₂ are sequentially stacked, but is not limited thereto. The stacking order may vary depending on the type of the layer 20 and/or the type of pattern to be formed through photolithography. The multilayer molecular film photoresist 30 can be formed using the atomic layer deposition equipment or molecular layer deposition equipment described with reference to FIG. 4.

As an example, a light-absorbing layer FL₁ may be formed on the layer 20. Forming the light-absorbing layer FL₁ can be performed using the atomic layer deposition method described with reference to FIGS. 3 and 4, specifically, the molecular layer deposition method.

In one example, the light-absorbing layer FL₁ may be formed by performing a cycle including forming a light-absorbing metal monolayer M1 and forming an organic molecular layer O1 multiple times (11 in Formula 1A). In the step of forming the organic molecular layer O1, a unit cycle comprising an organic precursor dosing step of dosing an organic precursor and chemically bonding the organic precursor to the underlying layer through self-assembly; and a purge step of purging unreacted organic precursors and reaction by-products by supplying a purge gas may be performed. The purge gas may be argon.

The organic precursor may be represented by Formula 4. In the organic precursor dosing step, a reaction according to Scheme 1 may occur.

In the step of forming a light-absorbing metal monolayer M1, a unit cycle comprising a metal precursor dosing step of dosing a metal precursor and chemically bonding the metal precursor to the underlying layer by self-assembly; and a purge step of purging unreacted metal precursors and reaction by-products by supplying a purge gas may be performed. The purge gas may be argon.

The metal precursor for forming the light-absorbing metal monolayer MI may be represented by the following formula 5A.

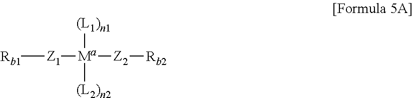

In Formula 5A, R_{b1} and R_{b2} may be, regardless of each other, a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted linear or branched alkyl groups. Z₁, Z₂, L₁, L₂, n1, n2, and M^{a} are as defined in Formula 2A. In addition, in some cases, two of R_{b1}, R_{b2}, L₁, and L₂ may be combined with M^{a} to which they are directly or indirectly bonded to form heterocyclyl or heteroaryl. Alternatively, at least one of R_{b1} and R_{b2} may be coordinated to M^{a}.

As an example, Z₁ and Z₂ may be bonds, and L₁, L₂, R_{b1}, and R_{b2} may be the same functional groups. As another example, Z₁ and Z₂ may be bonds, L₁ and L₂ may be the same functional groups, and R_{b1} and R_{b2} may be the same functional groups, but L₁ and R_{b1} may be different functional groups.

Specific examples of metal precursors for forming the light-absorbing metal monolayer MI may be as follows.

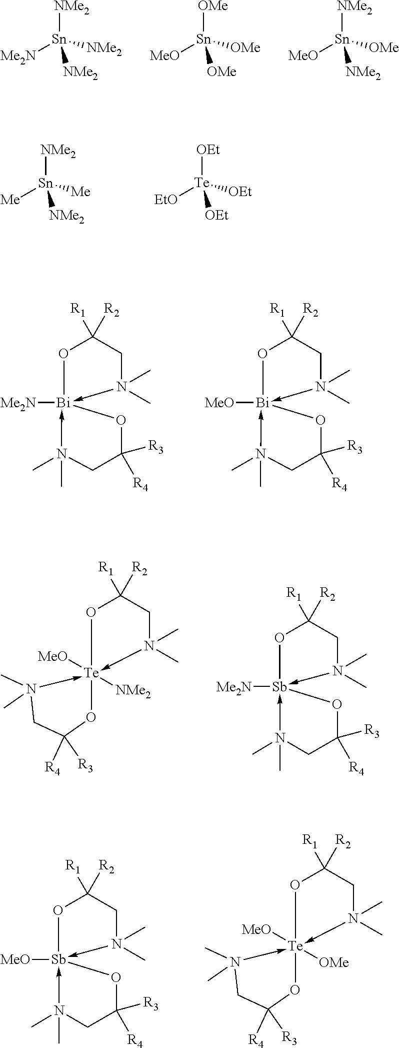

In the metal precursors, R₁, R₂, R₃, and R₄ may be C1 to C5 alkyl groups regardless of each other.

In the metal precursor dosing step, a reaction according to Scheme 2A below may occur.

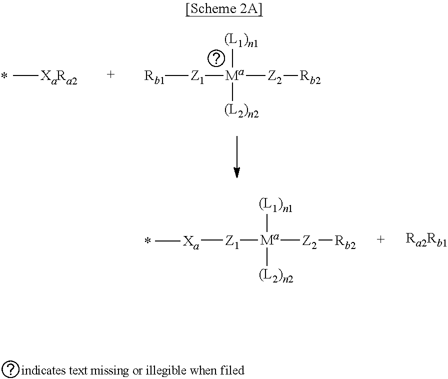

In Scheme 2A, *—XₐRₐ₂ may be a surface functional group of the underlying layer, specifically, the surface functional group of the organic molecular layer O1 formed previously. The metal precursor of Formula 5A may self-assemble on the surface of the organic molecular layer O1 by reacting with the surface functional group of the previously formed organic molecular layer O1. During this process, Rₐ₂R_{b1} may be produced as a reaction by-product. After this, the remaining metal precursor and the reaction by-products may be purged in the purge step. In Scheme 2A, each functional group may be the same as defined in Formula 4 and Formula 5A.

Unlike shown, when the light-absorbing layer FL₁ is formed of a plurality of metal monomolecular layers M1 (when n1 in Formula 1A is 2 or more), after performing the metal precursor dosing step and purge step according to Scheme 4 described above, a unit cycle comprising a reaction gas dosing step of dosing a reaction gas to react with the metal precursor chemically bonded to the underlying layer, a purge step of supplying a purge gas to purge unreacted reaction gas and reaction by-products, the metal precursor dosing step, and the purge step may be repeated. The reaction gas may be hydrogen, a gas containing oxygen (ex. O₂, O₃, H₂O), or a gas containing nitrogen (ex. NH₃).

A photoreactive layer FL₂ may be formed on the light-absorbing layer FL₁ or on the substrate before forming the light-absorbing layer FL₁. Forming the photoreactive layer FL₂ may be performed using the atomic layer deposition method described with reference to FIGS. 3 and 4, specifically, the molecular layer deposition method.

As an example, the photoreactive layer FL₂ may be formed by performing a cycle including forming a photoreactive metal monolayer M₂ and forming an organic molecular layer O2. The organic molecular layer O2 may be formed using the same or similar method to the method of forming the organic molecular layer O1 described in the light-absorbing layer FL₁. However, in the organic precursor dosing step of Scheme 1, —R₀ may be replaced with -R_{b2}, which is the terminal group of the metal precursor self-assembled on the underlying layer described in Scheme 2.

The photoreactive metal monolayer M₂ may be formed by performing a unit cycle including a metal precursor dosing step of dosing a metal precursor and chemically bonding the metal precursor to the underlying layer by self-assembly; and a purge step of purging unreacted metal precursors and reaction by-products by supplying a purge gas. The purge gas may be argon.

The metal precursor for forming the photoreactive metal monolayer M₂ may be represented by the following formula 5B.

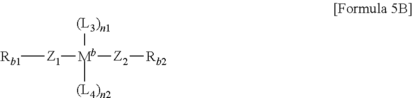

In Formula 5B, R_{b1} and R_{b2} may be, regardless of each other, a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted linear or branched alkyl groups. Z₁, Z₂, L₃, L₄, n1, n2, and M^{b} are as defined in Formula 2B. In addition, in some cases, two of R_{b1}, R_{b2}, L₃, and L₄ may be combined with M^{b} to which they are directly or indirectly bonded to form heterocyclyl or heteroaryl. Alternatively, at least one of R_{b1} and R_{b2} may be coordinated to M^{b}.

As an example, Z₁ and Z₂ may be bonds, and L₃, L₄, R_{b1}, and R_{b2} may be the same functional groups. As another example, Z₁ and Z₂ may be bonds, L₃ and L₄ may be the same functional groups, and R_{b1} and R_{b2} may be the same functional groups, but L₃ and R_{b1} may be different functional groups.

Specific examples of metal precursors for forming the photoreactive metal monolayer M₂ may be as follows.

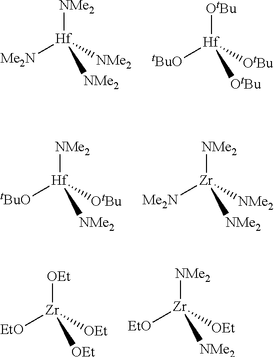

In the metal precursor dosing step, a reaction according to Scheme 2B below may occur.

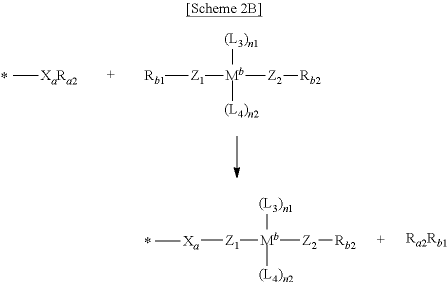

In Scheme 2B, *—XₐRₐ₂ may be a surface functional group of the underlying layer, specifically, the surface functional group of the organic molecular layer O2 formed previously. The metal precursor of Formula 5B may self-assemble on the surface of the organic molecular layer O2 by reacting with the surface functional group of the previously formed organic molecular layer O2. During this process, Rₐ₂R_{b1} may be produced as a reaction by-product. After this, the remaining metal precursor and the reaction by-products may be purged in the purge step. In Scheme 2B, each functional group may be the same as defined in Formula 4 and Formula 5B.

Unlike shown, when the photoreactive layer FL₂ is formed to include a plurality of metal monomolecular layers M₂ (when n2 in Formula 1B is 2 or more), after performing the metal precursor dosing step and purge step according to Scheme 2B described above, a unit cycle comprising a reaction gas dosing step of dosing a reaction gas to react with the metal precursor chemically bonded to the underlying layer, a purge step of supplying a purge gas to purge unreacted reaction gas and reaction by-products, the metal precursor dosing step, and the purge step may be repeated. The reaction gas may be hydrogen, a gas containing oxygen (ex. O₂, O₃, H₂O), or a gas containing nitrogen (ex. NH₃).

An etch-resistant layer FL₃ may be formed on the photoreactive layer FL₂ or on the substrate before forming the light-absorbing layer FL₁. Forming the etch-resistant layer FL₃ may be performed using the atomic layer deposition method described with reference to FIGS. 3 and 4, specifically, the molecular layer deposition method.

As an example, the etch-resistant layer FL₃ may be formed by performing a cycle including forming an etch-resistant metal monolayer M₃ and forming an organic molecular layer O3. The organic molecular layer O3 may be formed using the same or similar method to the method of forming the organic molecular layer O1 described in the light-absorbing layer FL₁. However, in the organic precursor dosing step of Scheme 1, —R₀ may be a surface functional group bonded to the surface on the etch target layer.

The etch-resistant metal monolayer M₃ may be formed by performing a unit cycle including a metal precursor dosing step of dosing a metal precursor and chemically bonding the metal precursor to the underlying layer by self-assembly; and a purge step of purging unreacted metal precursors and reaction by-products by supplying a purge gas. The purge gas may be argon.

The metal precursor for forming the etch-resistant metal monolayer M₃ may be represented by the following formula 5C.

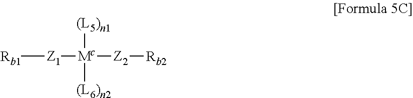

In Formula 5C, R_{b1} and R_{b2} may be, regardless of each other, a halogen group (ex. Cl, Br, or I), a C1 to C5 alkyl group, a C1 to C5 alkylsilylamino group, a C1 to C5 alkoxy group, a C1 to C5 alkylthio group, a C1 to C5 alkylseleno group, a C1 to C5 alkylamino group, or a C1 to C5 alkylphosphino group. The C1 to C5 alkyl groups may be substituted or unsubstituted linear or branched alkyl groups. Z₁, Z₂, L₅, L₆, n1, n2, and M^{c} are as defined in Formula 2C. In addition, in some cases, two of R_{b1}, R_{b2}, L₅, and L₆ may be combined with M^{c} to which they are directly or indirectly bonded to form heterocyclyl or heteroaryl. Alternatively, at least one of R_{b1} and R_{b2} may be coordinated to M^{c}.

As an example, Z₁ and Z₂ may be bonds, and L₅, L₆, R_{b1}, and R_{b2} may be the same functional groups. As another example, Z₁ and Z₂ may be bonds, L₅ and L₆ may be the same functional groups, and R_{b1} and R_{b2} may be the same functional groups, but L₅ and R_{b1} may be different functional groups.

Specific examples of metal precursors for forming the etch-resistant metal monolayer M₃ may be as follows.

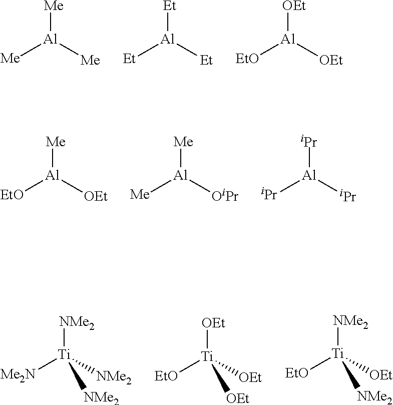

In the metal precursor dosing step, a reaction according to Scheme 2C below may occur.

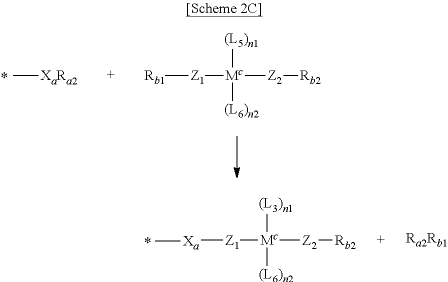

In Scheme 2C, *—XₐRₐ₂ may be a surface functional group of the underlying layer, specifically, the surface functional group of the organic molecular layer O3 formed previously. The metal precursor of Formula 5C may self-assemble on the surface of the organic molecular layer O3 by reacting with the surface functional group of the previously formed organic molecular layer O3. During this process, Rₐ₂R_{b1} may be produced as a reaction by-product. After this, the remaining metal precursor and the reaction by-products may be purged in the purge step. In Scheme 2C, each functional group may be the same as defined in Formula 4 and Formula 5B.

Unlike shown, when the etch-resistant layer FL₃ is formed to include a plurality of metal monomolecular layers M3 (when n3 in Formula 1C is 2 or more), after performing the metal precursor dosing step and purge step according to Scheme 3C described above, a unit cycle comprising a reaction gas dosing step of dosing a reaction gas to react with the metal precursor chemically bonded to the underlying layer, a purge step of supplying a purge gas to purge unreacted reaction gas and reaction by-products, the metal precursor dosing step, and the purge step may be repeated. The reaction gas may be hydrogen, a gas containing oxygen (ex. O₂, O₃, H₂O), or a gas containing nitrogen (ex. NH₃).

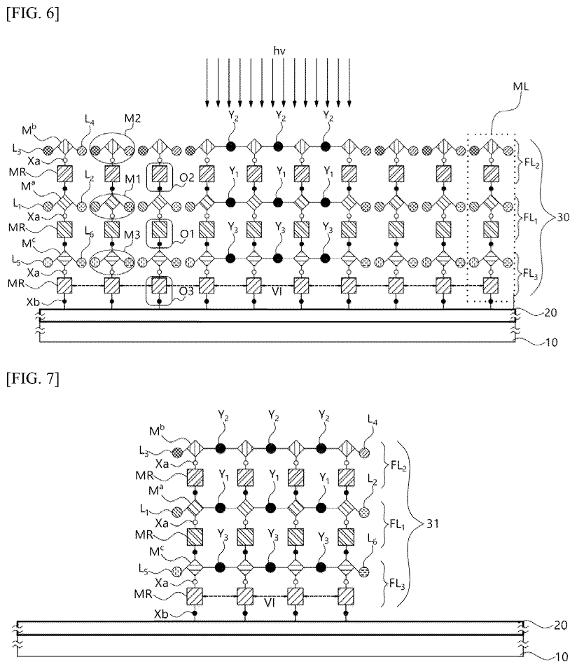

Referring to FIG. 6, radiation hv, specifically EUV or Ebeam, may be irradiated to a portion of the multilayer molecular film photoresist 30. In this case, M^{a}, a metal atom having a 4d or 5d orbital as an example of a d orbital in the light absorption layer FL₁, may absorb the radiation and generate secondary electrons. However, the present invention is not limited to this, and metal atoms or other elements in the photoreactive layer FL₂ and/or the etch-resistant layer FL₃ may also absorb radiation and generate secondary electrons.

Crosslinks may be formed between photoreactive inorganic single molecules M₂ in adjacent molecular lines ML by secondary electrons generated in the light absorption layer FL₁. Specifically, M^{b}-L₄ and L₃ -M^{b} in the photoreactive inorganic single molecules M₂ adjacent to each other may react by the secondary electrons to form M^{b}-Y₂-M^{b} bond. Y₂ may be O, S, Se, N, or P. Additionally, crosslinks may be formed between the light-absorbing inorganic single molecules M1 in adjacent molecular lines ML by secondary electrons generated in the light-absorbing layer FL₁. Specifically, M^{a}-L₂ and L₁-M^{a} bonds in the light-absorbing inorganic single molecules M1 may react with the secondary electrons to form M^{a}-Y₁-M^{a} bond. Y₁ may be O, S, Se, N, or P. In addition, crosslinks may also be formed between the etch-resistant inorganic single molecules M₃ in adjacent molecular lines ML by secondary electrons generated in the light absorption layer FL₁. Specifically, M^{c}-L₆ and L₅-M^{c} bonds in the etch-resistant inorganic single molecules M₃ may react with the secondary electrons to form M^{c}-Y₃-M^{c} bond. Y₃ may be O, S, Se, N, or P.

Referring to FIG. 7, the multilayer molecular film photoresist 30 exposed to radiation may be exposed to a developer. In this case, the portion where crosslinks are not formed between the inorganic single molecules (M1, M2, and M3) in the adjacent molecular lines ML may removed by the developer to form a multilayer molecular film photoresist pattern 31. The developer may be a developing solution, such as water, isopropyl alcohol (IPA), methyl isobutyl ketone (MIBK), tetramethylammonium hydroxide (TMAH), or a developing gas, such as CF₄, Ar, O₂, CHF₃, etc., or a plasma generated from this.

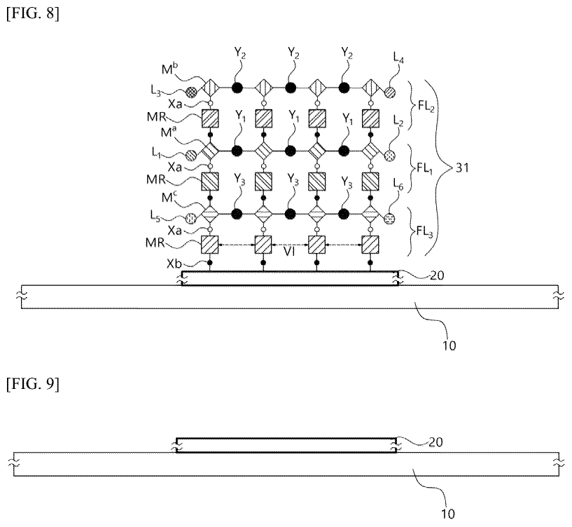

Referring to FIG. 8, the etch target layer 20 may be etched using the multilayer molecular film photoresist pattern 31 as a mask. As an example, this etching may be plasma etching. The etching resistance of the multilayer molecular film photoresist pattern 31 may be increased due to the M^{c}-Y₃-M^{c} bond between the etch-resistant inorganic single molecules M3, allowing the etch target layer 20 to be selectively etched.

Referring to FIG. 9, the multilayer molecular film photoresist pattern 31 can be removed. This can be accomplished using the ashing method.

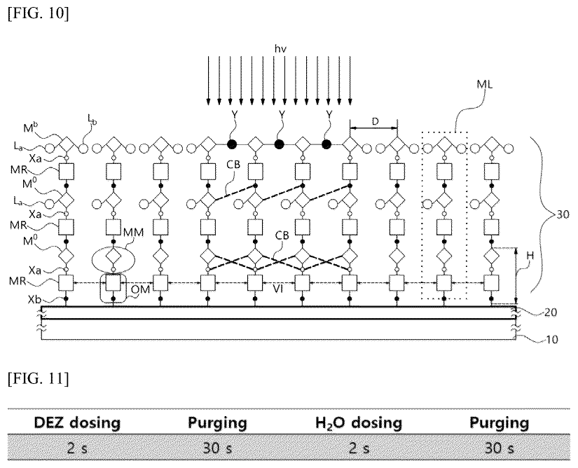

FIG. 10 is a schematic diagram showing a photolithography method according to another embodiment of the present invention, limited to the exposure step of FIG. 6. Except for this, it may be the same as the embodiment described with reference to FIGS. 3 to 9.

Referring to FIG. 10, when the unit layer is —[X_{b}—MR—Xₐ—M⁰ ]—, the metal precursor used to form the first unit layer shows the case where the sum of na and nb in Formula 5 is 0, the metal precursor used to form the second unit layer shows the case where the sum of na and nb in Formula 5 is 1, and the metal precursor used to form the third unit layer shows the case where the sum of na and nb in Formula 5 is 2. However, it is not limited to this, and one type of metal precursor can be used and the stacking order can also be different.

When this photoresist is exposed to radiation, if the sum of na and nb is 0, M⁰ can bond to Xₐ and/or X_{b} of another adjacent molecular line via, specifically, coordinate bond (CB). When the sum of na and nb is 1, M⁰ can bond with Xₐ and/or X_{b} of another adjacent molecular line via, specifically, coordinate bond (CB), or M⁰-Lₐ and Lₐ -M⁰ bonds may form M⁰ -Y-M⁰ bond. This M⁰ -Y-M⁰ bond, and the bond between M⁰ and Xₐ and/or X_{b} may not be etched by a developer that develops a multilayer molecular film photoresist film after exposure. The developer may be a developing gas or developing plasma. Y may be C, O, S, Se, N, or P.

As described above, the multilayer molecular film photoresist 30 according to an embodiment of the present invention may be formed by self-assembly of inorganic single molecules and organic single molecules connected by bonds within the molecular lines, so that each molecular line can grow upward over the substrate without being entangled or tilted, and the molecular lines can be uniformly arranged in the horizontal direction.

The molecular lines may be formed so densely that van der Waals interactions VI can occur between organic single molecules in adjacent molecular lines. The van der Waals interaction can play a role in stabilizing horizontally adjacent molecular lines and preventing the pattern from collapsing even when it has a high aspect ratio. In this way, the dense formation of molecular lines may be due to the organic precursor and/or metal precursor dosing being performed without using a carrier gas to increase the pressure of the organic precursor and/or metal precursor in the chamber. For this purpose, dosing of organic precursors and/or metal precursors can be carried out with the gas outlet of the chamber closed. In this case, the height (H in FIG. 10) of the unit layer which is —[X_{b}—MR—Xₐ—M⁰ ]— or —[X_{b}—Z₃—MR—Z₄—Xₐ—Z₁—M⁰—Z₂]— may be approximately equal to the length of the unit layer which reflects the actual sizes of atoms in the unit layer and the actual length of the bonds between atoms.

In this case, the gap between the molecular lines (D in FIG. 1 or FIG. 3) may be very small, such as 1 nm or less, specifically 0.5 nm or less. In addition, due to the separation between molecular lines rather than particles during exposure and development, the Line Edge Roughness (LER), which refers to the roughness of the side of the pattern, can be very low at 1.2 nm or less, and the resolution is also 6 nm or less. In addition, the multilayer molecular film photoresist 30 can exhibit high photosensitivity (ex. 10 mJ/cm²) with low stochastic failure even for EUV with low photon density.

In addition, when the organic single molecule OM further includes a C1 to C2 alkyl group(s) (Rₐ₃ in Formula 3A) bonded directly or indirectly to the side of the body (MR in Formula 3), the van der Waals interaction between organic single molecules OM can be greater, and in this case, the greater van der Waals interaction can further stabilize horizontally adjacent molecular lines, preventing the pattern from collapsing even when having a high aspect ratio. In addition, when the organometallic single molecule does not have a side ligand or has a side ligand(s) with air stability, it can prevent crosslinking from occurring due to a reaction by moisture from the air inside the photoresist during storage after forming the photoresist.

Hereinafter, a preferred experimental example is presented to help understanding of the present invention. However, the following experimental examples are only to aid the understanding of the present invention, and the present invention is not limited by the following experimental examples.

FIG. 11 shows a unit cycle configuration for forming an inorganic molecular layer.

Referring to FIG. 11, a unit cycle including dosing DEZ (diethylzinc) into the chamber for 2 seconds, purging the chamber for 30 seconds, dosing water (H₂O) for 2 seconds, and purging the chamber for 30 seconds was performed multiple times (30 times) to form a ZnO inorganic molecular layer.

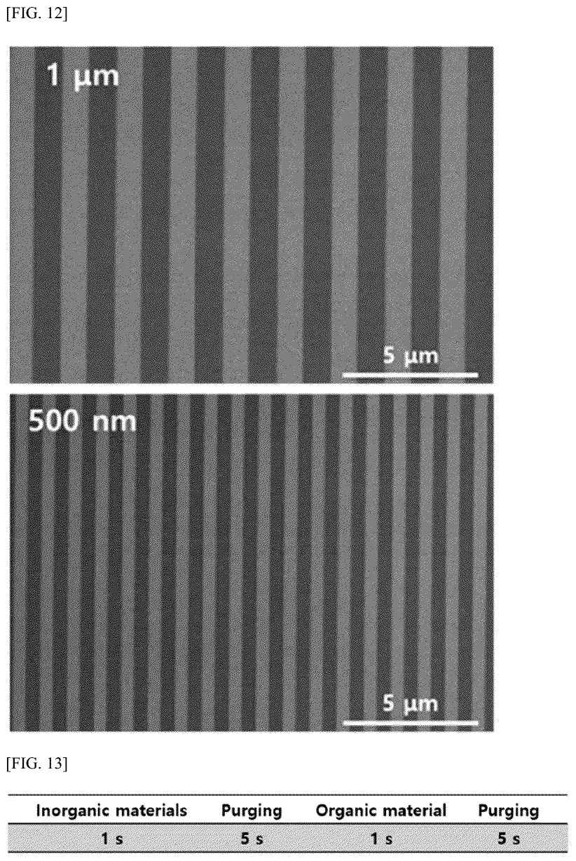

FIG. 12 is an SEM image taken after patterning the vertically designed inorganic multilayer molecular film photoresist formed with reference to FIG. 11. Specifically, after irradiating an e-beam on a vertically designed inorganic multilayer molecular film formed with reference to FIG. 11 under a voltage of 100 kV and a dose of 2500 uC/cm², the film was developed by ultrasonic treatment in TMAH (Tetramethylammonium hydroxide) in H₂O for 2 minutes.

Referring to FIG. 12, it can be seen that a pattern with a line width of 1 μm and a pattern with a line width of 500 nm were clearly formed.

### PREPARATION EXAMPLE 1: HF-BASED PHOTORESIST PREPARATION EXAMPLE

FIG. 13 shows an example of a unit cycle configuration for forming a multilayer molecular film photoresist having a vertical molecular line structure.

Referring to FIG. 13, a substrate was loaded into a chamber equipped with a gas inlet and a gas outlet, and the substrate temperature was heated to 100° C. With the gas outlet closed, tetrakisdimethylamido Hafnium, an Hf precursor, was supplied as a metal precursor to the substrate through the gas inlet without a carrier gas, until the pressure in the chamber reached 1 Torr (metal precursor supply step). Afterwards, the chamber inlet was also closed and the Hf precursor was reacted with the surface of the substrate for 1 second while maintaining the chamber pressure at 1 Torr (metal precursor exposure step). Afterwards, with both the gas inlet and gas outlet open, argon, a purge gas, was supplied to the gas inlet for 5 seconds to purge reaction by-products and remaining reaction gas (metal precursor purge step). The metal precursor supply step, the metal precursor exposure step, and the metal precursor purge step constituted a metal precursor subcycle.

Afterwards, with the gas outlet closed, 4-mercaptophenol as an organic precursor was supplied onto the Hf precursor layer through the gas inlet without a carrier gas, until the pressure in the chamber reached 200 mTorr (organic precursor supply step). Afterwards, the chamber inlet was also closed and the organic precursor was reacted on the Hf precursor layer for 1 second while maintaining the chamber pressure at 200 mTorr (organic precursor exposure step). Afterwards, with both the gas inlet and gas outlet open, argon, a purge gas, was supplied to the gas inlet for 5 seconds to purge reaction by-products and remaining reaction gas (organic precursor purge step). The organic precursor supply step, the organic precursor exposure step, and the organic precursor purge step constitute an organic precursor subcycle.

A unit cycle consisting of one metal precursor subcycle and one organic precursor subcycle was performed 30 times to form a multilayer molecular film photoresist with a thickness of about 20 nm.

### PREPARATION EXAMPLE 2: TI-BASED PHOTORESIST PREPARATION EXAMPLE

A multilayer molecular film photoresist was prepared in the same manner as Preparation Example 1, except that tetrakisdimethylamido Titanium, a Ti precursor, was used as the metal precursor instead of tetrakisdimethylamido Hafnium, an Hf precursor, thereby forming a multilayer molecular film photoresist with a thickness of approximately 15 nm.

### PREPARATION EXAMPLE 3: AL-BASED PHOTORESIST PREPARATION EXAMPLE

A multilayer molecular film photoresist was manufactured in the same manner as Preparation Example 1, except that trimethyl aluminum, an Al precursor, was used as the metal precursor instead of tetrakisdimethylamido hafnium, an Hf precursor, thereby forming a multilayer molecular film photoresist with a thickness of about 20 nm.

### PREPARATION EXAMPLE 4: ZN-BASED PHOTORESIST PREPARATION EXAMPLE

A multilayer molecular film photoresist was prepared in the same manner as Preparation Example 1, except that DEZ (diethylzinc), a Zn precursor, was used as the metal precursor instead of tetrakisdimethylamido hafnium, an Hf precursor, thereby forming a multilayer molecular film photoresist with a thickness of about 20 nm.

### PREPARATION EXAMPLE 5: ZN-BASED PHOTORESIST PREPARATION EXAMPLE

A multilayer molecular film photoresist was prepared in the same manner as Preparation Example 1, except that DEZ (diethylzinc), a Zn precursor, was used as the metal precursor instead of tetrakisdimethylamido hafnium, an Hf precursor, and 3-methyl-3-mercapto-butanol is used instead of 4-mercaptophenol as an organic precursor. The thickness of the multilayer molecular film photoresist was about 15 nm.

### Comparative Example 1: Hf-Based Film

A substrate was loaded into a chamber equipped with a gas inlet and a gas outlet, and the substrate temperature was heated to 100° C. With the gas outlet of the chamber open, the Hf precursor, tetrakisdimethylamido hafnium, was supplied along with the carrier gas, argon, until the pressure in the chamber reached 300 mTorr (metal precursor supply step). The partial pressure of the Hf precursor was 10 mTorr. The Hf precursor was reacted on the substrate surface for 1 second while the pressure in the chamber was maintained at 300 mTorr (metal precursor exposure step). Afterwards, with both the gas inlet and gas outlet open, argon, a purge gas, was supplied to the gas inlet for 5 seconds to purge reaction by-products and remaining reaction gas (metal precursor purge step). The metal precursor supply step, the metal precursor exposure step, and the metal precursor purge step constitute a metal precursor subcycle.

Afterwards, with the gas outlet open, 4-mercaptophenol as an organic precursor along with argon as a carrier gas was supplied onto the Hf precursor layer through the gas inlet, until the pressure in the chamber reached 300 mTorr (organic precursor supply step). The partial pressure of the organic precursor was 8 mTorr. Afterwards, the organic precursor was reacted on the Hf precursor layer for 1 second while maintaining the chamber pressure at 300 mTorr (organic precursor exposure step). Afterwards, with both the gas inlet and gas outlet open, argon, a purge gas, was supplied to the gas inlet for 5 seconds to purge reaction by-products and remaining reaction gas (organic precursor purge step). The organic precursor supply step, the organic precursor exposure step, and the organic precursor purge step constituted an organic precursor subcycle.

A unit cycle consisting of one metal precursor subcycle and one organic precursor subcycle was performed 70 times to form a multilayer molecular film photoresist with a thickness of about 20 nm.

### Comparative Example 2: Zn-Based Film

A multilayer molecular film photoresist was manufactured in the same manner as Comparative Example 1, except that DEZ (diethylzinc), a Zn precursor, was used as the metal precursor instead of tetrakisdimethylamido hafnium, an Hf precursor. The thickness of the multilayer molecular film photoresist was about 20 nm.

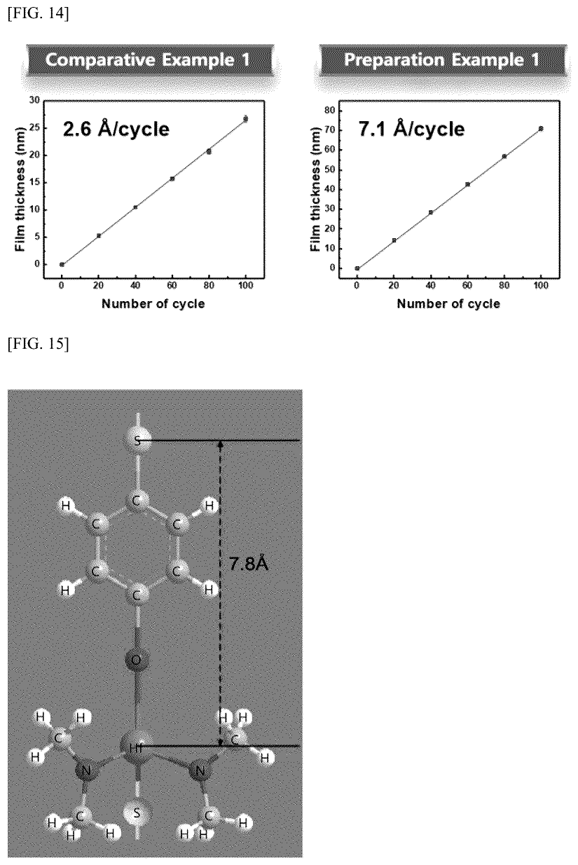

FIG. 14 shows graphs showing the film thickness versus the number of unit cycle repetitions in manufacturing the Hf-based photoresist according to Preparation Example 1 and Comparative Example 1.

Referring to FIG. 14, the Hf-based photoresist according to Preparation Example 1 was formed to a thickness of about 7.1 Å per unit cycle, while the Hf-based photoresist according to Comparative Example 1 was formed to a thickness of about 2.6 Å per unit cycle.

FIG. 15 is a schematic diagram showing expected unit product obtained through the reaction of the Hf precursor and organic precursor used in Preparation Example 1 and Comparative Example 1. FIG. 15 was obtained using chemdraw and reflects the actual size of the atoms and the actual length of the bonds between the atoms.

Referring to FIG. 15, it can be seen that the unit product obtained by reacting one molecule of the Hf precursor and one molecule of the organic precursor used in Preparation Example 1 and Comparative Example 1 has a unit length of about 7.8 Å.

Referring to FIGS. 14 and 15 simultaneously, the Hf-based photoresist according to Preparation Example 1 was formed with a thickness of about 7.1 Å per unit cycle, and the thickness is similar to the length of the expected product, about 7.8 Å, which is the length of the expected unit product obtained by reacting one molecule of the Hf precursor and one molecule of the organic precursor. On the other hand, the Hf-based film according to Comparative Example 1 was formed to a thickness of about 2.6 Å per unit cycle, which is 1/3 of about 7.8 Å, which is the length of the expected unit product obtained by reacting one molecule of the Hf precursor with one molecule of the organic precursor. From this, when a unit cycle is performed in the production of the Hf-based photoresist according to Preparation Example 1, it can be assumed that the main chain (or molecular line) of the product obtained by reacting the Hf precursor and the organic precursor on the substrate does not lie down or tilt on the substrate but substantially grows vertically to the substrate. It can be understood that this phenomenon is caused by reacting the precursors with the underlying layer while being densely arranged on the underlying layer, and furthermore by reacting the precursors with the underlying layer in a state of the chamber outlet is closed. The densely arranged precursors on the underlying layer can be made by increasing precursor dosing pressure through pressurizing the Hf precursor to 1 Torr without a carrier gas when dosing the Hf precursor and pressurizing 4-mercaptophenol, which is an organic precursor, to 200 mTorr when dosing 4-mercaptophenol in the chamber. Also, in this case, as described above, van der Waals interactions may occur between organic molecules within the molecular lines, and due to this van der Waals interaction, even if the thickness of the photoresist increases, the molecular lines do not collapse and a substantial vertical direction growth of the molecular lines can be maintained.

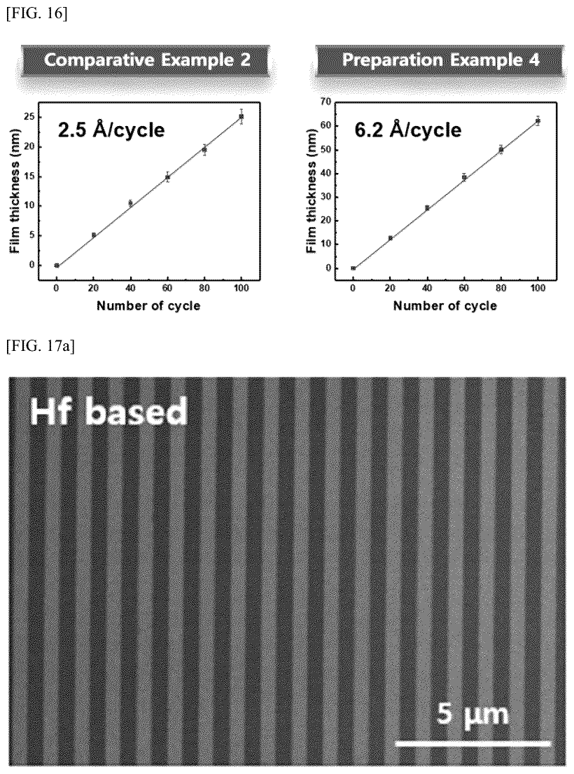

FIG. 16 shows graphs showing the film thickness versus the number of unit cycle repetitions in manufacturing the Zn-based photoresist according to Preparation Example 4 and Comparative Example 2.

Referring to FIG. 16, the Zn-based photoresist according to Comparative Example 2 was formed to a thickness of about 2.5 Å per unit cycle, while the Zn-based photoresist according to Preparation Example 4 was formed to a thickness of about 6.2 Å per unit cycle, that is much larger than that of Comparative Example 2. As explained with reference to FIGS. 14 and 15, when a unit cycle is performed in the production of Zn-based photoresist according to Preparation Example 4, the main chain (or molecular line) of the product obtained by reacting the Zn precursor and the organic precursor on the substrate can be assumed to grow upward over the substrate, specifically in a substantially vertical direction to the substrate, without lying down or tilting on the substrate.

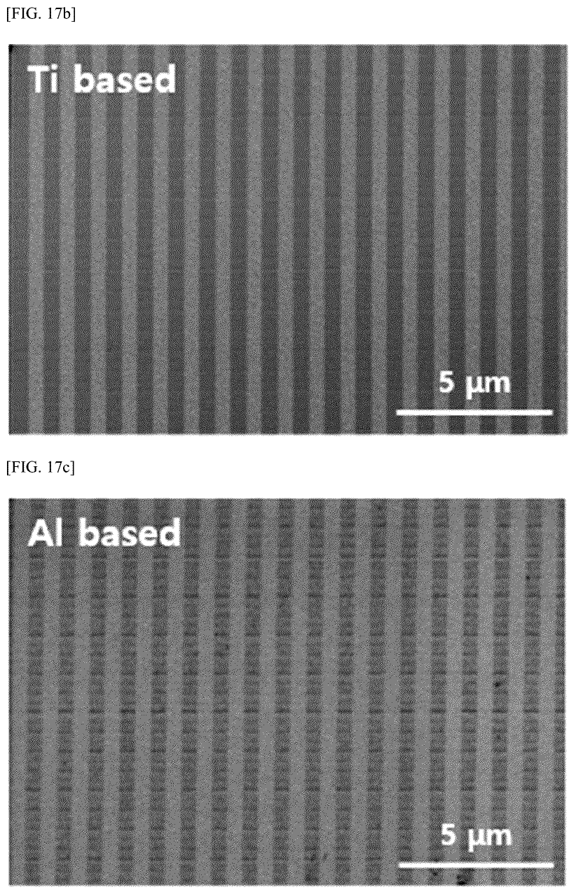

FIGS. 17a, 17b, and 17c are SEM images taken after patterning the photoresist obtained in Preparation Examples 1 to 3. Specifically, the photoresist obtained in Preparation Examples 1 to 3 was exposed to e-beam under conditions of a voltage of 100 kV, 100 pA, and a dose of 2500 uC/cm², and then developed by ultrasonicating in TMAH (tetramethylammonium hydroxide) in H₂O for 2 minutes.

Referring to FIGS. 17a, 17b, and 17c, it can be seen that a pattern with a half pitch of 500 nm was clearly formed. The remained portion of the photoresist is the exposed portion, so the photoresist according to this embodiment can be defined as a negative photoresist.

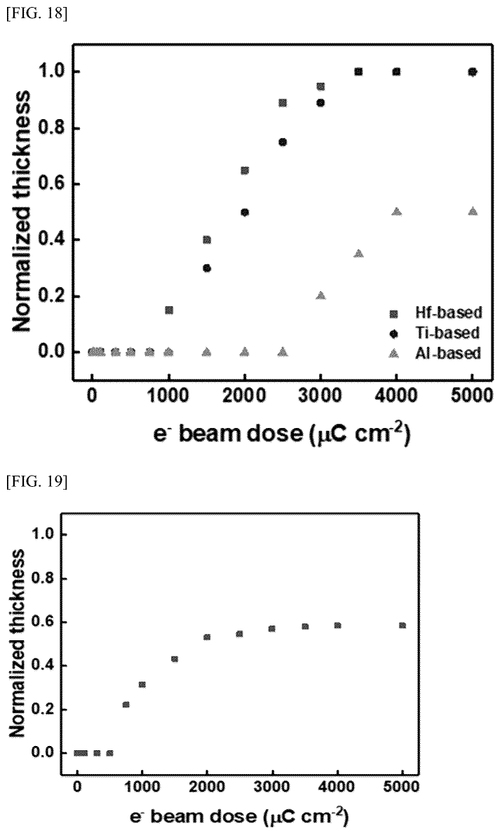

FIG. 18 is a graph showing the sensitivity to electron beam of the photoresist obtained in Preparation Examples 1 to 3. Specifically, the photoresist obtained in Preparation Examples 1 to 3 was exposed to e-beam under conditions of a voltage of 100 kV, 100 pA, and a dose of 1 to 5,000 uC/cm², and then developed by ultrasonic treatment in TMAH (tetramethylammonium hydroxide) in H₂O for 2 minutes, and the thickness of the pattern was measured according to the exposure amount.

Referring to FIG. 18, the normalized thickness of the negative photoresist in this experiment is indicated as 1 when the thickness immediately after deposition is maintained even after development, and the multilayer molecular film photoresist formed using the Hf precursor according to Preparation Example 1 can be seen to have the best sensitivity as it shows a normalized thickness of 1 at the lowest e-beam dose.

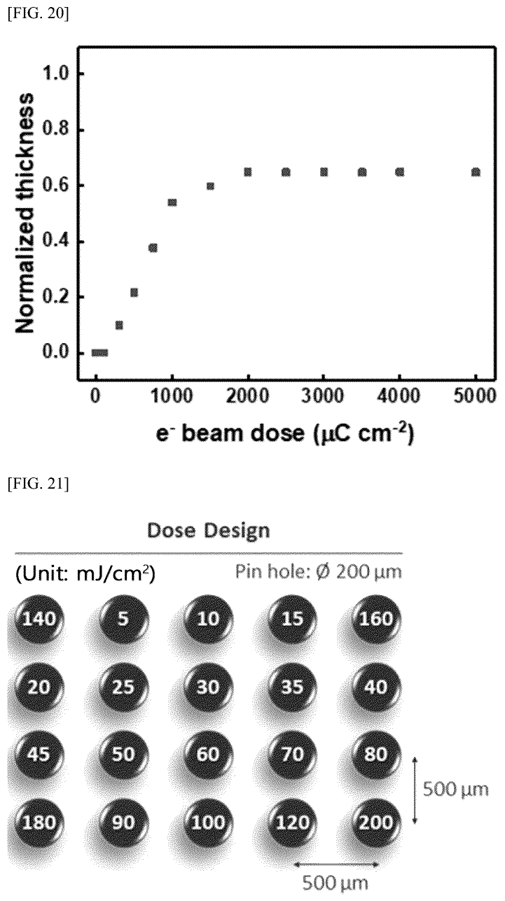

FIG. 19 is a graph showing the sensitivity of the photoresist obtained in Preparation Example 4 to electron beam. FIG. 20 is a graph showing the sensitivity of the photoresist obtained in Preparation Example 5 to electron beam.

Specifically, the photoresist obtained in Preparation Example 4 was exposed by being irradiated with an e-beam under a voltage of 100 kV, 100 pA, and a dose of 1 to 5000 uC/cm², and the photoresist obtained in Preparation Example 5 was exposed by being irradiated with an e-beam under a voltage of 100 kV, 100 pA, and dose of 1 to 5000 uC/cm², then the exposed photoresists were developed by dipping in TMAH (tetramethylammonium hydroxide) in H₂O for 10 seconds. Then, the thickness of the pattern was measured and shown. The normalized thickness of the negative photoresist was indicated as 1 when the thickness immediately after deposition was maintained even after development.

Referring to FIG. 19, it can be seen that the multilayer molecular film photoresist according to Preparation Example 4 formed using Zn precursor as the metal precursor and 4-mercaptophenol as the organic precursor has a normalized thickness of 0.5 at about 1100 uC/cm².

Referring to FIG. 20, the multilayer molecular film photoresist according to Preparation Example 5 formed using a Zn precursor and 3-methyl-3-mercapto-butanol as an organic precursor has a normalized thickness of 0.5 at about 700uC/cm².

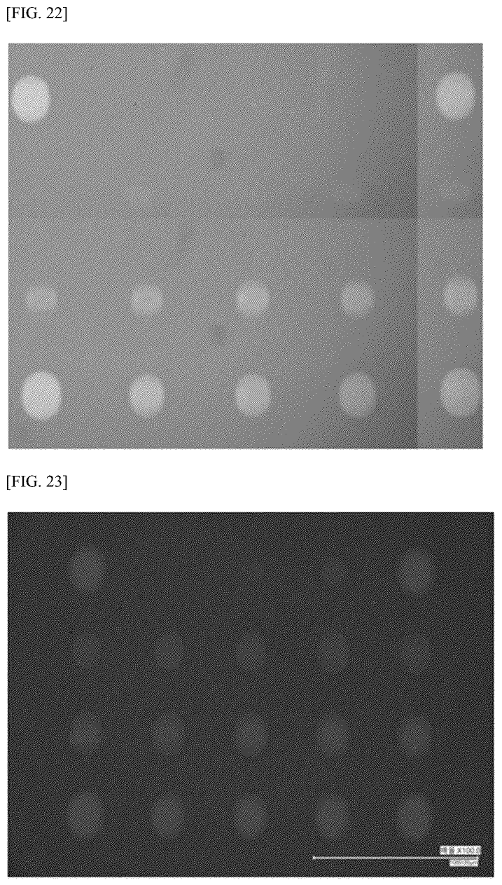

FIG. 21 is a schematic diagram showing the form and dose conditions of EUV irradiation, and FIGS. 22, 23, and 24 are optical photos taken of photoresist patterns obtained after irradiating photoresists according to Preparation Example 1, Preparation Example 4, and Preparation Example 5 with the EUV patterns shown in FIG. 21, respectively. Specifically, FIG. 22 is a photograph of a photoresist pattern obtained by exposing the photoresist according to Preparation Example 1 to an EUV pattern as shown in FIG. 21 and then developing by ultrasonicating it in TMAH (tetramethylammonium hydroxide) in H₂O for 2 minutes. FIGS. 23 and 24 are photographs of a photoresist patterns obtained by exposing the photoresist according to Preparation Examples 4 and 5 to an EUV pattern as shown in FIG. 21 and then developing by dipping it in TMAH (tetramethylammonium hydroxide) in H₂O for 10 seconds.

Referring to FIGS. 21 and 22, the photoresist obtained using Hf precursor as the metal precursor and 4-mercaptophenol as the organic precursor according to Preparation Example 1 has a thickness of about 20 nm immediately after deposition, and has a thickness of about 10 nm or more after being exposed to EUV at a dose of about 60 mJ/cm² or more and developed. From this, it can be seen that the EUV sensitivity of the Hf-based photoresist according to Preparation Example 1 is 60 mJ/cm².

Referring to FIGS. 21 and 23, the photoresist obtained using Zn precursor as the metal precursor and 4-mercaptophenol as the organic precursor according to Preparation Example 4 has a thickness of about 20 nm immediately after deposition, and has a thickness of about 10 nm or more after being exposed to EUV at a dose of about 40 mJ/cm² or more and developed. From this, it can be seen that the EUV sensitivity of the Zn-based photoresist according to Preparation Example 4 is 40 mJ/cm².

Referring to FIGS. 21 and 24, the photoresist obtained using Zn precursor as the metal precursor and 3-methyl-3-mercapto-butanol as the organic precursor according to Preparation Example 5 has a thickness of about 20 nm immediately after deposition, and has a thickness of about 10 nm or more after being exposed to EUV at a dose of about 20 mJ/cm² or more and developed. From this, it can be seen that the EUV sensitivity of the Zn-based photoresist according to Preparation Example 5 is 20 mJ/cm².

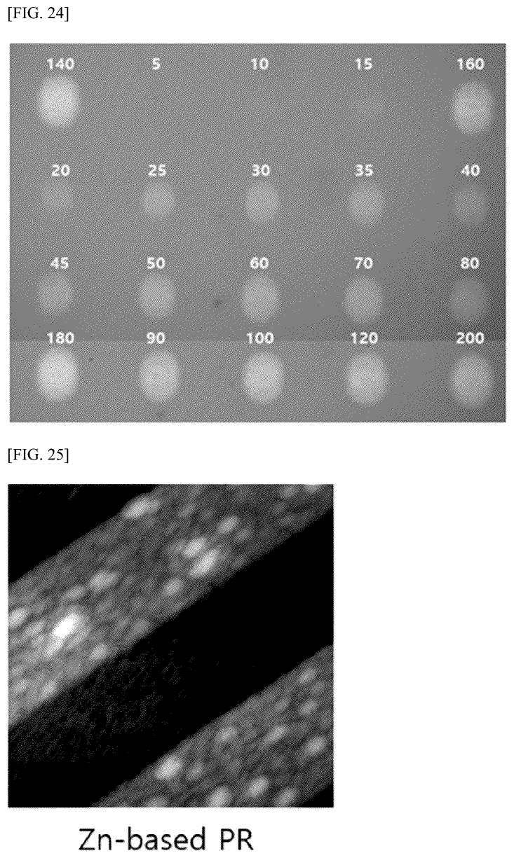

FIG. 25 is an AFM (Atomic force microscopy) image obtained after electron beam exposure and development of a photoresist using a Zn precursor according to Preparation Example 4, and FIG. 26 is an AFM (Atomic force microscopy) image obtained after electron beam exposure and development of a PMMA photoresist. The PMMA photoresist was obtained by applying a solution of PMMA dissolved in chlorobenzene on a substrate, then irradiating it with an electron beam, and removing the irradiated part through development to obtain a pattern. The two photoresists were commonly irradiated with electron beam under the conditions of voltage of 100 kV, 100 pA, and dose of 2500 uC/cm². After electron beam exposure, the two photoresists were sonicated in TMAH (tetramethylammonium hydroxide) in H₂O for 2 minutes, and the unexposed portions were removed.

Referring to FIGS. 25 and 26, it can be seen that the photoresist using the Zn precursor has lower line edge roughness than the PMMA photoresist.

### PREPARATION EXAMPLE 6: ZN-BASED PHOTORESIST PREPARATION EXAMPLE

A substrate was loaded into a chamber equipped with a gas inlet and a gas outlet, and the substrate temperature was heated to 100° C.

With the gas outlet closed, MMB (3-Mercapto-3-methylbutan-1-ol) as an organic precursor is supplied to the substrate through the gas inlet without a carrier gas until the pressure in the chamber reached 2 Torr (organic precursor supply step). Afterwards, the chamber inlet was also closed and the organic precursor was reacted on the substrate for 5 seconds while maintaining the chamber pressure at 2 Torr (organic precursor exposure step). Afterwards, with both the gas inlet and gas outlet open, argon, a purge gas, was supplied to the gas inlet for 800 seconds to purge reaction by-products and residual reaction gas (organic precursor purge step). The organic precursor supply step, the organic precursor exposure step, and the organic precursor purge step constitute an organic precursor subcycle.

Afterwards, with the gas outlet closed, DEZ (diethyl zinc) as a metal precursor was supplied onto the organic precursor layer through the gas inlet without a carrier gas, until the pressure in the chamber reached 1 Torr (metal precursor supply step).

Afterwards, the chamber inlet was also closed and the metal precursor was reacted on the surface of the organic precursor layer for 5 seconds while the chamber pressure was maintained at 1 Torr (metal precursor exposure step). Afterwards, with both the gas inlet and gas outlet open, argon, a purge gas, was supplied to the gas inlet for 200 seconds to purge reaction by-products and remaining reaction gas (metal precursor purge step). The metal precursor supply step, the metal precursor exposure step, and the metal precursor purge step constitute a metal precursor subcycle.

A unit cycle consisting of one metal precursor subcycle and one organic precursor subcycle was performed 54 times to form a multilayer molecular film photoresist with a thickness of about 20 nm.

The film formation speed was 3.7Å/cycle. This is similar to the length of the unit product obtained by reacting one molecule of the Zn precursor with one molecule of the organic precursor. From this, when a unit cycle is performed in the production of the photoresist according to the Preparation Example, it can be assumed that the main chain (or molecular line) of the product obtained by reacting the metal precursor and the organic precursor on the substrate does not lie or tilt on the substrate, but grows upward over the substrate, specifically, grows in a substantially vertical direction to the substrate. This means that the distance between organic molecules within the molecular lines is narrow enough for van der Waals interaction to occur, and due to this van der Waals interaction, even if the thickness of the photoresist increases, the molecular lines do not collapse and growth in a substantially vertical direction can be maintained.

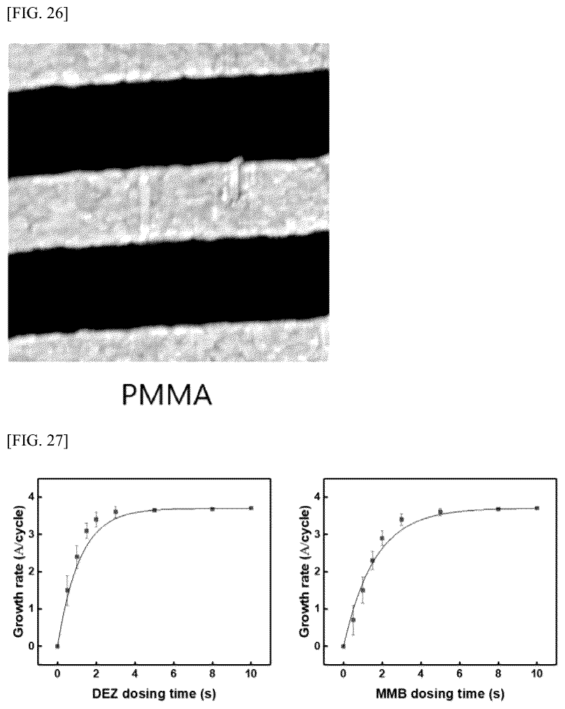

FIG. 27 shows graphs showing the film formation speed according to the supply time of each precursor in manufacturing the photoresist according to

Preparation Example 6. The left graph shows the change in film formation speed while changing the DEZ supply time with the MMB supply time fixed at 5 seconds, and the right graph shows the film formation speed while changing the MMB supply time with the DEZ supply time fixed at 5 seconds.

Referring to FIG. 27, it can be seen that the deposition speed is saturated after the DEZ supply time is about 4 seconds, and the deposition speed is saturated after the MMB supply time is about 5 seconds. Accordingly, in Preparation Example 6, the DEZ supply time was set to 5 seconds and the MMB supply time was set to 5 seconds to obtain a film forming speed of approximately 3.7 Å/cycle.

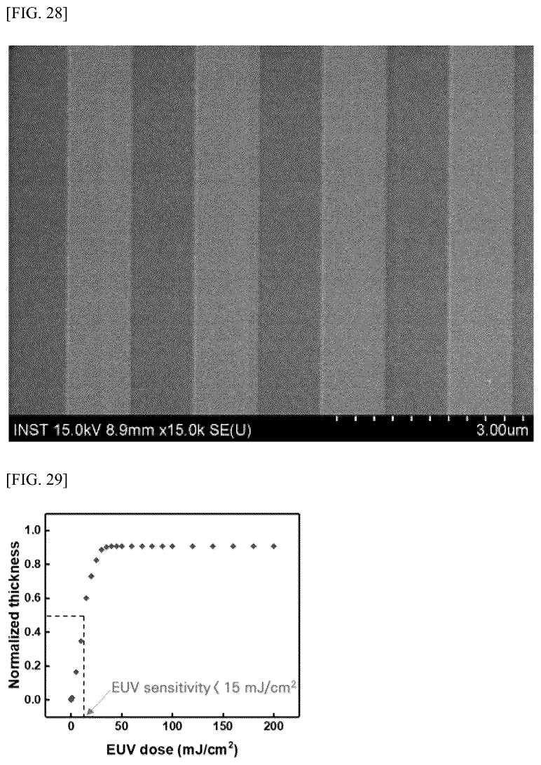

FIG. 28 is an SEM image taken after patterning the photoresist obtained in Preparation Example 6. Specifically, the photoresist obtained in Preparation Example 6 was exposed to an e-beam under the conditions of a voltage of 15 kV, a beam current of 0.13 nA, and a dose of 300 uC/cm², and soaked in 10 wt % TMAH (tetramethylammonium hydroxide) in H₂O for 10 seconds and then soaked in H₂O for 10 seconds.

Referring to FIG. 28, it can be seen that a pattern with a half pitch of 1 μm was clearly formed. The embossed pattern is formed in the exposed portion, so the photoresist according to this embodiment can be defined as a negative photoresist.

FIG. 29 is a graph showing the sensitivity of the photoresist obtained in Preparation Example 6 to EUV. Specifically, the photoresist obtained in Preparation Example 6 was exposed to EUV dose conditions of 5 to 200 mJ/cm², immersed in 10 wt % TMAH (tetramethylammonium hydroxide) in H₂O for 10 seconds, and then immersed in H₂O for 10 seconds for development.

Referring to FIG. 29, the normalized thickness of the negative photoresist in this experiment was indicated as 1 when the thickness immediately after deposition was maintained even after development, and it can be seen that the multilayer molecular film photoresist according to the preparation example has excellent sensitivity as it shows a normalized thickness of 0.5 at less than 15 mJ/cm².

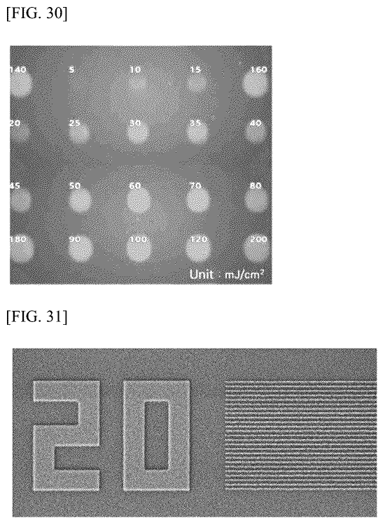

FIG. 30 is an optical photograph of a photoresist pattern obtained by irradiating the EUV pattern shown in FIG. 21 to the photoresist according to Preparation Example 6 and then developing it. Specifically, the photoresist according to Preparation Example 6 was exposed to EUV pattern as shown in FIG. 21, then immersed in 10 wt % TMAH (tetramethylammonium hydroxide) in H₂O for 10 seconds, and then dipped in H₂O for 10 seconds for development.

Referring to FIG. 30, the photoresist according to Preparation Example 6 shows a thickness of about 20 nm immediately after deposition, and the photoresist pattern shows a thickness of about 10 nm or more when exposed at a dose of about 10 mJ/cm² or more and developed. From this, it can be seen that the EUV sensitivity of the photoresist according to the preparation example is 10 mJ/cm².

FIG. 31 is an SEM image of a photoresist pattern obtained by irradiating EUV to the photoresist according to Preparation Example 6 and then developing it. Specifically, the photoresist according to Preparation Example 6 was exposed to 30 mJ/cm² of EUV, then immersed in 10 wt % TMAH (tetramethylammonium hydroxide) in H₂O for 10 seconds, and then immersed in H₂O for 10 seconds for development.

Referring to FIG. 31, it can be seen that a pattern with a half pitch of 20 nm was clearly formed.

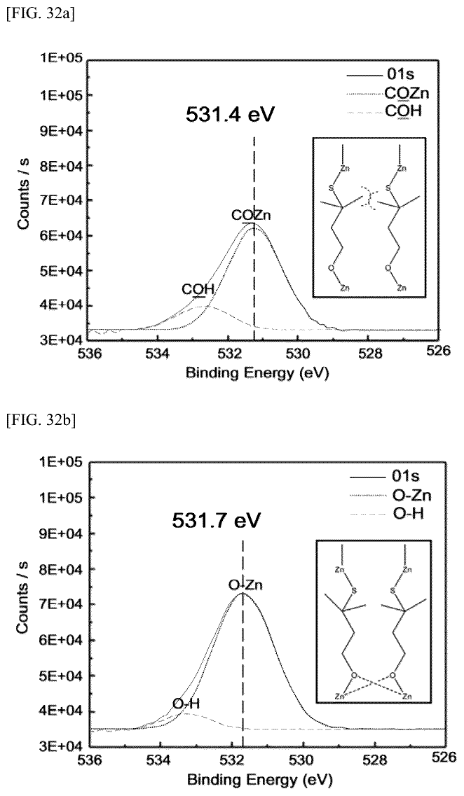

FIGS. 32a and 32b show O1s XPS (X-ray Photoelectron spectroscopy) analysis data before and after EUV exposure of the photoresist according to Preparation Example 6, respectively.

Referring to FIG. 32a, the O1s peak corresponding to the C—O—Zn bond before exposure appeared at 531.4 eV.

Referring to FIG. 32b, the O1s peak corresponding to the C—O—Zn bond (or O—Zn bond) after exposure appears at 531.7 eV, showing that it has moved to a high-binding energy compared to before exposure. This may mean that, in addition to the C—O—Zn bond before exposure, a coordination bond (dotted line in inset) (corresponding to CB in FIG. 10) was created between O and Zn due to exposure.

While the exemplary embodiments of the present invention have been described above, those of ordinary skill in the art should understood that various changes, substitutions and alterations may be made herein without departing from the spirit and scope of the present invention as defined by the following claims.

1. A multilayer molecular film photoresist comprising:
a plurality of molecular lines extending upwards above a substrate arranged in the horizontal direction,
wherein each of the molecular lines includes a plurality of inorganic single molecules and an organic single molecule sandwiched between at least some of the inorganic single molecules, and these single molecules are connected by bonds.

2. The multilayer molecular film photoresist of claim 1, wherein Van der Waals interaction occurs between the organic single molecules in horizontally adjacent molecular lines among the molecular lines.

3. The multilayer molecular film photoresist of claim 2, wherein each of the organic single molecules has an aromatic ring or a linear or branched alkylene group, and the van der Waals interaction is a π-π bond between the aromatic rings or a van der Waals interaction between the alkylene groups.

4. The multilayer molecular film photoresist of claim 1, wherein, within each of the molecular lines, the inorganic single molecules and the organic single molecules are alternately stacked.

5. The multilayer molecular film photoresist of claim 1, wherein the inorganic single molecule is an organometallic single molecule containing Sn, Sb, Te, Bi, Zr, Al, Hf, Zn, In, Ti, Cu, W, or Si as a central metal.

6. The multilayer molecular film photoresist of claim 1, wherein some of identical inorganic single molecules among the inorganic single molecules provided in the molecular lines are located at the same level to form an inorganic monomolecular layer in the horizontal direction, and wherein some of identical organic single molecules among the organic single molecules provided in the molecular lines are located at the same level to form an organic monomolecular layer in the horizontal direction.

7. The multilayer molecular film photoresist of claim 6, wherein the multilayer molecular film photoresist includes at least one layer of a light-absorbing layer including a light-absorbing inorganic single molecule, a photoreactive layer including a photoreactive inorganic single molecule, and an etch-resistant layer including an etch-resistant inorganic single molecule.

8. The multilayer molecular film photoresist of claim 7, wherein the light-absorbing inorganic single molecule is an inorganic single molecule having a metal element having a d orbital.

9. The multilayer molecular film photoresist of claim 8, wherein the metal element having the d orbital is Sn, Sb, Te, or Bi.

10. The multilayer molecular film photoresist of claim 7, wherein the photoreactive inorganic molecule has a metal element of Zr, Al, Hf, Zn, or In.

11. The multilayer molecular film photoresist of claim 7, wherein the etch-resistant inorganic single molecule has a metal element of Al, Ti, W, Zn, Si, or Cu.

12. The multilayer molecular film photoresist of claim 1, wherein the multilayer molecular film photoresist is a photoresist for EUV.

13. The multilayer molecular film photoresist comprising:
a plurality of molecular lines each extending upwards above a substrate and arranged in the horizontal direction, wherein each of the molecular lines has a portion represented by the following Formula 1: 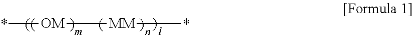
in Formula 1, one of the *s is a bond with a functional group in an underlying portion, the other is a bond with a functional group in an upper portion, MM is an inorganic single molecule containing a metal element, OM is an organic single molecule, and m is 1 to 2, n is 1 to 2, and 1 is 1 to 1000.

14. The multilayer molecular film photoresist of claim 13, wherein Van der Waals interaction exists between the organic single molecules in the horizontally adjacent molecular lines.

15. The multilayer molecular film photoresist of claim 13, wherein the organic single molecule is represented by the following Formula 3:
*—X_{b}—Z₃—MR—Z₄—* [Formula 3]
in Formula 3, one of the *s is a bond with a functional group in an underlying portion, the other is a bond with a functional group in an upper portion, X_{b} is O, S, Se, NR (R is H or CH₃) or PR (R is H or CH₃),
MR is a substituted or unsubstituted aromatic ring, a C1 to C18 substituted or unsubstituted linear alkylene group, or a C1 to C18 substituted or unsubstituted branched alkylene group,
each of Z₃ and Z₄ independently is a bond, a substituted or unsubstituted linear alkylene group of C1 to C5, or a substituted or unsubstituted branched alkylene group of C1 to C5 when MR is the aromatic ring, Z₃ and Z₄ are bonds when MR is the alkylene group.

16. The multilayer molecular film photoresist of claim 15, wherein Van der Waals interaction exists between the organic single molecules in the horizontally adjacent molecular lines, and
the van der Waals interaction is a π-π bond between aromatic rings when the MR is an aromatic ring, or the van der Waals interaction is a van der Waals interaction between alkylene groups when the MR is a linear or branched alkylene group.

17. The multilayer molecular film photoresist of claim 15, wherein the organic single molecule represented by the Formula 3 is an organic single molecule represented by Formula 3A below: 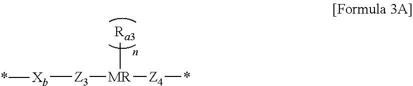
in Formula 3A, Rₐ₃ is an alkyl group of C1 to C2, n is 0 to 2, and *, X_{b}, MR, Z₃ and Z₄ are as defined in Formula 3 above.

18. The multilayer molecular film photoresist of claim 17, wherein the MR is a C2 to C6 linear alkylene group.

19. The multilayer molecular film photoresist of claim 13, wherein the inorganic single molecule is an organometallic single molecule represented by the following Formula 2: 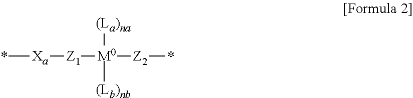
in Formula 2, one of the *s is a bond with a functional group in an underlying portion, the other is a bond with a functional group in an upper portion,
Xₐ is O, S, Se, NR (R is H or CH₃) or PR (R is H or CH₃),
M⁰ is a center metal and is Sn, Sb, Te, Bi, Zr, Al, Hf, Zn, In, Al, Ti, Cu, W, or Si,
each of Z₁ and Z₂ independently is a bond, a substituted or unsubstituted linear or branched alkylene group of C1 to C20, a substituted or unsubstituted linear or branched alkyleneoxide of C1 to C20, a substituted or unsubstituted linear or branched alkyleneamino of C1 to C20, a substituted or unsubstituted linear or branched alkylenesilylamino of C1 to C20, a substituted or unsubstituted linear or branched alkylenethio of C1 to C20, a substituted or unsubstituted linear or branched alkyleneseleno of C1 to C20, or a substituted or unsubstituted linear or branched alkylenephosphino of C1 to C20,
each of Lₐ and L_{b} independently is a halogen group, a C1 to C5 alkyl group, a C1 to C5 alkylsilylamino group, C1 to C5 alkoxy group, C1 to C5 alkylthio group, C1 to C5 alkylseleno group, C1 to C5 alkylamino group, C1 to C5 alkylphosphino group, acetate, or aryloxy,
a sum of nₐ and n_{b} is an integer from 0 to 4

20. The multilayer molecular film photoresist of claim 19, wherein both of nₐ and n_{b} are 0.
